(19) United States
(12) Patent Application Publication
(10) Pub. No.: US 2013/0134492 A1
(43) Pub. Date: May 30, 2013

(54) SEMICONDUCTOR MEMORY DEVICES AND METHODS FOR FABRICATING THE SAME

(71) Applicants: Junkyu YANG, Seoul (KR); Phil Ouk NAM, Hwaseong-si (KR); JinGyun KIM, Yongin-si (KR); Jaeyoung AHN, Seongnam-si (KR); SeungHyun LIM, Seoul (KR); Kihyun HWANG, Seongnam-si (KR)

(72) Inventors: Junkyu YANG, Seoul (KR); Phil Ouk NAM, Hwaseong-si (KR); JinGyun KIM, Yongin-si (KR); Jaeyoung AHN, Seongnam-si (KR); SeungHyun LIM, Seoul (KR); Kihyun HWANG, Seongnam-si (KR)

(21) Appl. No.: 13/587,379

(22) Filed: Aug. 16, 2012

(30) Foreign Application Priority Data
Nov. 24, 2011 (KR) 10-2011-0123530

(51) Int. Cl. H01L 29/78

(52) U.S. Cl. 257/314; 257/E29.262

(57) ABSTRACT

Example embodiments of inventive concepts relate to semiconductor memory devices and/or methods for fabricating the same. The semiconductor memory device may include a plurality of gates vertically stacked on a substrate, a vertical channel penetrating the plurality of gates and a data storage layer between the vertical channel and the plurality of gates. The vertical channel may include a lower channel connected to the substrate and an upper channel on the lower channel. The upper channel may include a vertical pattern penetrating some of the plurality of gates and defining an inner space filled with an insulating layer, and a horizontal pattern horizontally extending along a top surface of the lower channel. The horizontal pattern may be in contact with the top surface of the lower channel.

### CROSS-REFERENCE TO RELATED APPLICATIONS

This U.S. non-provisional patent application claims priority under 35 U.S.C. §119 to Korean Patent Application No. 10-2011-0123530, filed on Nov. 24, 2011, the entire disclosure of which is incorporated by reference herein.

### BACKGROUND

Example embodiments of inventive concepts relate to semiconductors and, more particularly, to semiconductor memory devices and/or methods for fabricating the same.

Semiconductor devices are attractive in the electronic industry because of small size, multi-function and/or low fabrication cost thereof. High performance semiconductor devices and/or low cost semiconductor devices have been increasingly demanded with the development of the electronic industry. Some semiconductor devices have been more highly integrated. In particular, it may be desirable to increase the integration density of semiconductor memory devices to store logic data.

In two-dimensional semiconductor memory devices, a planar area in which a unit memory cell occupies may directly affect the integration density of the two dimensional semiconductor memory devices. Thus, the integration density of the two dimensional semiconductor memory devices may be influenced by a minimum feature size which relates to a process technology for forming fine patterns. However, there may be challenges in improving the process technology for forming the fines patterns. In addition, high cost equipment or apparatus may be used to form the fine patterns. Thus, cost for fabricating the highly integrated semiconductor memory devices may be increased. Three dimensional semiconductor memory devices have been proposed. Three dimensional semiconductor memory devices may include a plurality of memory cells which are three dimensionally arrayed.

### SUMMARY

Example embodiments of inventive concepts relate to three-dimensional (3D) semiconductor memory devices and/or methods for fabricating the same.

According to example embodiments of inventive concepts, a semiconductor memory device may include: a plurality of gates vertically stacked on a substrate; a vertical channel penetrating the plurality of gates; and a data storage pattern between the vertical channel and the plurality of gates. The vertical channel includes a lower channel connected to the substrate and an upper channel on the lower channel. The upper channel may include a vertical pattern penetrating some of the plurality of gates and defining an inner space. The inner space may be filled with an insulating layer. The upper channel includes a horizontal pattern that extends horizontally along a top surface of the lower channel and contacts the top surface of the lower channel. The horizontal pattern may constitute a bottom surface of the inner space.

A material of the lower channel may be the same as material of the substrate. For example, if the substrate contains silicon, the lower channel may include single-crystalline silicon.

A width of the horizontal pattern of the upper channel may be greater than or equal to a width of the top surface of the lower channel.

The horizontal pattern may surround an upper portion of a sidewall of the lower channel. For example, the horizontal pattern may have a bottle cap shape.

The vertical pattern may include a multi-layer structure including a first semiconductor layer in contact with the data storage pattern and a second semiconductor layer in contact with and surrounding the insulating layer. Alternatively, the vertical pattern may include a single-layer surrounding the insulating layer, where the single-layer may be in contact with the data storage pattern and the insulating layer.

The upper channel of the vertical channel may extend vertically and unevenly.

The plurality of gates may include sidewalls and sidewall-corners, and the upper channel of the vertical channel may include bent portions that are adjacent to the sidewalls and sidewall-corners of the plurality of gates.

The data storage pattern may vertically extend along the upper channel and be separated from the lower channel. The data storage pattern may include a blocking insulating layer adjacent to the gates, a tunnel insulating layer adjacent to the upper channel, and a trap insulating layer disposed between the blocking insulating layer and the tunnel insulating layer.

The data storage pattern may include: a first data storage pattern vertically extending along the upper channel and being separated from the lower channel, the first data storage pattern including a tunnel insulating layer adjacent to the upper channel; and a second data storage pattern disposed between the gates and the vertical channel, the second data storage pattern including a blocking insulating layer covering top surfaces and bottom surfaces of the gates. Here, one of the first and second data storage patterns may include a trap insulating layer.

Portions of the upper channel adjacent to sidewalls and sidewall-corners of the gates may be bent.

According to example embodiments of inventive concepts, a semiconductor memory device may include: a gate stack on a substrate, the gate stack including a plurality of gates between a plurality of insulating layers; a vertical channel hole vertically penetrating the gate stack, the vertical channel including a lower channel hole exposing the substrate and an upper channel hole connected from the lower channel; a vertical channel including a lower channel and an upper channel, the lower channel filling the lower channel hole and contacting the substrate, and the upper channel filling the upper channel hole and contacting the lower channel; and a data storage pattern between the vertical channel and the gates. The upper channel may include: an insulating layer occupying a center region of the upper channel hole; and a semiconductor layer surrounding the filling layer. The semiconductor layer may include: a vertical pattern vertically extending along an inner sidewall of the upper channel hole and surrounding a sidewall of the filling layer; and a horizontal pattern horizontally extending a top surface of the lower channel, covering a bottom surface of the filling layer, and contacting the top surface of the lower channel.

The lower channel may include a single-crystalline semiconductor penetrating at least one gate adjacent to the substrate of the gates.

The upper channel hole may have a width that is greater than a width of the lower channel hole.

Sidewalls of the insulating layers adjacent to the upper channel may be laterally recessed as compared with sidewalls of the gates so that the inner sidewall of the upper channel hole may be non-uniform.

At least one of a surface of the upper channel and a surface of the data storage pattern, which are adjacent to the upper channel hole, may be uneven along the inner sidewall of the upper channel hole.

The data storage pattern may extend along the inner sidewall of the upper channel hole so that the data storage pattern may be in contact with the vertical pattern. The horizontal pattern may separate the data storage pattern from the lower channel.

The semiconductor memory device may further include a gate insulating layer between the lower channel and at least one gate adjacent to the lower channel.

The lower channel may be protruded toward the horizontal pattern. The horizontal pattern may surround an upper portion of the sidewall of the lower channel.

The semiconductor layer may include a poly-crystalline semiconductor having a cross section of U-shape.

The horizontal pattern may be a single-layer structure including the poly-crystalline semiconductor. The vertical pattern may be one of a single-layer and a multi-layer structure including the poly-crystalline semiconductor.

According to example embodiments of inventive concepts, a semiconductor memory device may include: at least one lower gate and a plurality of upper gates stacked on a substrate; a vertical channel including a lower channel and an upper channel, the lower channel vertically penetrating the lower gate and contacting the substrate, and the upper channel vertically penetrating the upper gates and contacting the lower channel; an upper gate insulating layer disposed between the upper channel and the upper gates; and a lower gate insulating layer disposed between the lower channel and the lower gate. The upper channel may include: an insulating pillar penetrating the upper gates; a semiconductor layer surrounding a sidewall of the insulating pillar; and a body contact extending from the semiconductor layer to cover a bottom surface of the insulating layer, the body contact contacting the lower channel.

The upper gate insulating layer may vertically extend along the semiconductor layer to be in contact with the semiconductor layer and the body contact. The body contact may separate the upper gate insulating layer from the lower channel.

The body contact may cover the top surface of the lower channel and surround an upper portion of the sidewall of the lower channel.

Portions of the upper channel adjacent to sidewalls and sidewall-corners of the gates may be bent.

The lower channel may include single-crystalline semiconductor. The upper channel may include poly-crystalline semiconductor.

The upper gate insulating layer may vertically extend along the semiconductor layer. The upper gate insulating layer may include a data storage pattern. The data storage pattern may have a tunnel insulating layer adjacent to the semiconductor layer, a blocking insulating layer adjacent to the upper gates, and a trap insulating layer disposed between the blocking insulating layer and the tunnel insulating layer. The lower gate insulating layer may include an oxide layer disposed on the sidewall of the lower channel and formed from the single-crystalline semiconductor.

The upper gates may include a plurality of memory gates and at least one upper selection gates sequentially stacked.

The memory gates may constitute word lines extending in a first horizontal direction on the substrate. The upper selection gate may constitute an upper selection line extending in the first horizontal direction over the word lines. The lower gate may constitute a lower selection line disposed under the word lines.

The semiconductor memory device may further include a bit line being electrically connected to the vertical channel and extending in a second horizontal direction crossing the first horizontal direction over the upper selection line.

The semiconductor memory device may further include: a drain doped with dopants in a top portion of the vertical channel; and a source doped with the dopants in substrate at a side of the lower gate. The drain may be electrically connected to the bit line.

According to example embodiments of inventive concepts, a method for fabricating a semiconductor memory device may include: forming a stacked structure including a lower channel on a substrate, the stacked structure defining a channel hole that exposes the lower channel; forming a data storage material layer extending along an inner surface of the channel hole, the data storage material layer covering an inner sidewall of the channel hole and a top surface of the lower channel; patterning the data storage material layer to form a data storage pattern along the sidewall of the channel hole, the data storage pattern being separated from the lower channel; and forming an upper channel to fill the channel hole, the upper channel extending vertically along the data storage pattern and extending horizontally along the top surface of the lower channel to occupy a separated space between the data storage pattern and the lower channel.

Forming the data storage pattern may include forming the separated space exposing the inner sidewall of the channel hole under the data storage pattern and the top surface of the lower channel.

Forming the data storage material layer may include forming a first semiconductor layer extending along the inner surface of the channel hole and covering the data storage material layer, and forming a spacer layer extending along the inner surface of the channel hole and covering the first semiconductor layer.

Forming the data storage pattern may include: performing an etch-back process on the spacer layer and the first semiconductor layer to expose a portion of the data storage material layer; and wet etching the exposed data storage material layer to form the data storage pattern vertical on the inner sidewall of the channel hole.

Forming the data storage pattern may include removing the spacer layer, and forming the separated space.

Forming the upper channel may include: forming a second semiconductor layer extending along the inner surface of the channel hole to cover the first semiconductor layer and fill the separated space; and forming an insulating filling layer filling the channel hole, the insulating filling layer being surrounded by the second semiconductor layer.

The forming the upper channel may include: removing the first semiconductor layer; forming a second semiconductor layer extending along the inner surface of the channel hole to cover the data storage pattern and fill the separated space; and forming an insulating filling layer that fills the channel hole, the insulating filling layer being surrounded by the second semiconductor layer.

The method may further include recessing the inner sidewall of the channel hole. The upper channel may extend vertically and unevenly along the recessed inner sidewall of the channel hole.

Forming the data storage material layer may include: forming a blocking insulating layer extending along the inner surface of the channel hole to cover the inner sidewall of the channel hole and the top surface of the lower channel; forming a trap insulating layer extending along the inner surface of the channel hole to cover the blocking insulating layer; and forming a tunnel insulating layer extending along the inner surface of the channel hole to cover the trap insulating layer.

Forming the stacked structure may include: alternately stacking a plurality of insulating layers and a plurality of sacrificial layers on the substrate; forming the channel hole penetrating the plurality of insulating layers and the plurality of sacrificial layers to expose the substrate; and forming the lower channel partially filling the channel hole and contacting the substrate.

The method may further include: patterning the stacked structure to form a trench exposing the substrate and sidewalls of the plurality of insulating layers and the plurality of sacrificial layers; providing an etchant through the trench to remove the plurality of sacrificial layers, thereby forming recess regions between the plurality insulating layers; filling the recess regions with a conductive material to form gates vertically stacked on the substrate; and forming a bit line electrically connected to the upper channel.

The method may further include: injecting dopants into the substrate through the trench, thereby forming a source; and injecting the dopants into a top portion of the upper channel, thereby forming a drain electrically connected to the bit line.

Before forming the gates, the method may further include at least one of the following: forming a second data storage pattern partially filling the recess regions; and forming a gate insulating layer on a sidewall of the lower channel exposed through the trench and at least one of the recess regions.

According to example embodiments of inventive concepts, a method for fabricating a semiconductor device includes: forming a stacked structure including a lower channel on a substrate, the stacked structure defining an opening that exposes the lower channel; forming a first data storage pattern that covers a sidewall of the opening and is spaced apart from the lower channel; forming an upper channel in the opening and on the lower channel of the stacked structure. The upper channel includes a base that extends horizontally between a top surface of the lower channel and a part of the first data storage pattern. The upper channel includes a vertical portion that extends over the substrate from the base of the upper channel.

The stacked structure may include a plurality of gate electrodes and a plurality of insulating interlayer that are alternately stacked on the substrate and define the opening that exposes the lower channel. The first data storage layer may be between at least one of the plurality of gate electrodes and the vertical portion of the upper channel.

The forming the upper channel in the opening and on the lower channel of the stacked structure may include: forming a preliminary stack that includes the lower channel on the substrate and defines a holes that exposes the lower channel, the preliminary stack including a plurality of sacrificial layers and a plurality of insulating interlayers alternately stacked on the substrate; forming an opening of the preliminary stack by widening the hole of the preliminary stack at a level of at least one of the plurality of insulating interlayers; forming the first data storage pattern and a first semiconductor pattern along a sidewall of the opening of the preliminary stack and spaced apart from the lower channel; forming a second semiconductor layer in the opening of the preliminary stack, the second semiconductor layer extending between the part of the first data storage pattern and the top surface of the lower channel and the second semiconductor layer and the second semiconductor layer extending vertically along the first semiconductor pattern; removing the plurality of sacrificial layers; and forming a plurality of gate electrodes between the plurality of insulating interlayers.

The forming the upper channel in the opening and on the lower channel of the stacked structure may include: sequentially forming a first data storage layer, a first semiconductor layer, and a spacer layer that cover a sidewall of the opening and the lower channel of the stacked structure; patterning the first data storage layer and the first semiconductor layer to form a first data storage pattern and a first semiconductor pattern that are spaced apart from the lower channel and extend along the sidewall of the opening of the stacked structure, the patterning the first data storage layer and the first semiconductor layer includes removing the spacer layer; and forming a second semiconductor layer and an insulating layer in the opening of the stacked structure, the second semiconductor layer and extending horizontally between the part of the first data storage pattern and the top surface of the lower channel and the second semiconductor layer extending vertically between the insulating layer and the first semiconductor pattern.

The stacked structure may include a plurality of lower channels, and may define a plurality of openings, where each one of the plurality of openings exposes one of the plurality of lower channels.

The base of the upper channel may contact a sidewall of the lower channel.

### BRIEF DESCRIPTION OF THE DRAWINGS

The foregoing and other features and advantages of example embodiments of inventive concepts will be apparent from the more particular description of non-limiting embodiments of inventive concepts, as illustrated in the accompanying drawings in which like reference characters refer to the same parts throughout the different views. The drawings are not necessarily to scale, emphasis instead being placed upon illustrating the principles of inventive concepts. In the drawings:

FIGS. 1A to 1K are cross-sectional views illustrating a method for fabricating a semiconductor memory device according to example embodiments of inventive concepts;

FIG. 1L is an enlarged view of a portion of FIG. 1;

FIGS. 2A to 2D are cross-sectional views illustrating an example of methods for forming an opening in a semiconductor memory device according to example embodiments of inventive concepts;

FIG. 2E is a cross-sectional view illustrating a step of a method for forming an opening in a semiconductor memory device according to example embodiments of inventive concepts;

FIGS. 3A to 3F are cross-sectional views illustrating steps of a method for fabricating a semiconductor memory device according to example embodiments of inventive concepts;

FIG. 3G is an enlarged view of a portion of FIG. 3F;

FIGS. 3H and 3I are cross-sectional views illustrating a steps in a method for fabricating a semiconductor memory device according to example embodiments of inventive concepts;

FIGS. 4A to 4G are cross-sectional views illustrating a method for fabricating a semiconductor memory device according to example embodiments of inventive concepts;

FIG. 4H is a cross-sectional view illustrating a step of a method for fabricating a semiconductor memory device according to example embodiments of inventive concepts;

FIGS. 5A to 5D are cross-sectional views illustrating a method for fabricating a semiconductor memory device according to example embodiments of inventive concepts;

FIGS. 5E to 5G are cross-sectional views illustrating steps of methods for fabricating a semiconductor memory device according to example embodiments of inventive concepts;

FIG. 6A is a schematic block diagram illustrating an example of memory cards including semiconductor memory devices according to example embodiments of inventive concepts; and

FIG. 6B is a schematic block diagram illustrating an example of information process systems including semiconductor memory devices according to example embodiments of inventive concepts.

### DETAILED DESCRIPTION OF EXAMPLE EMBODIMENTS

Example embodiments of inventive concepts will now be described more fully hereinafter with reference to the accompanying drawings, in which some example embodiments of inventive concepts are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of example embodiments of inventive concepts. Aspects of example embodiments of inventive concepts explained and illustrated herein include their complementary counterparts. The same reference numerals or the same reference designators denote the same elements throughout the specification.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

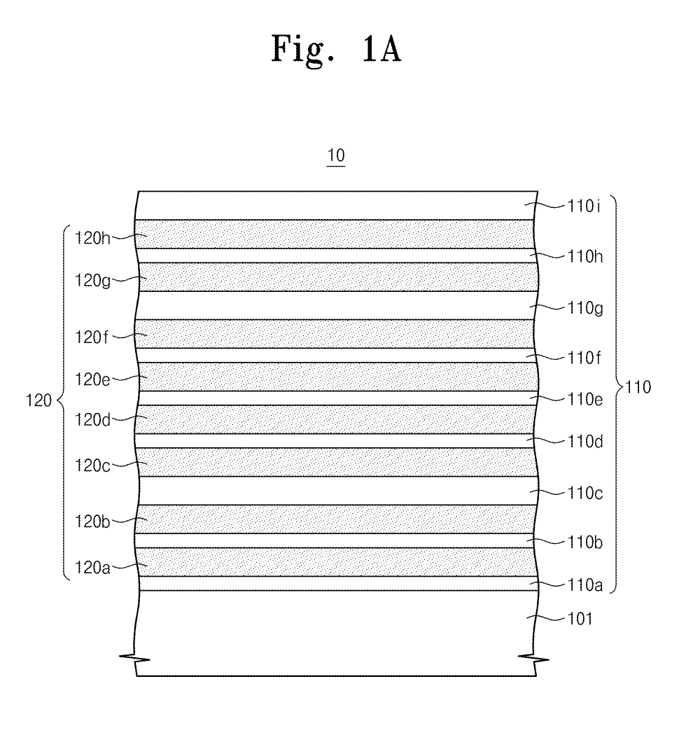

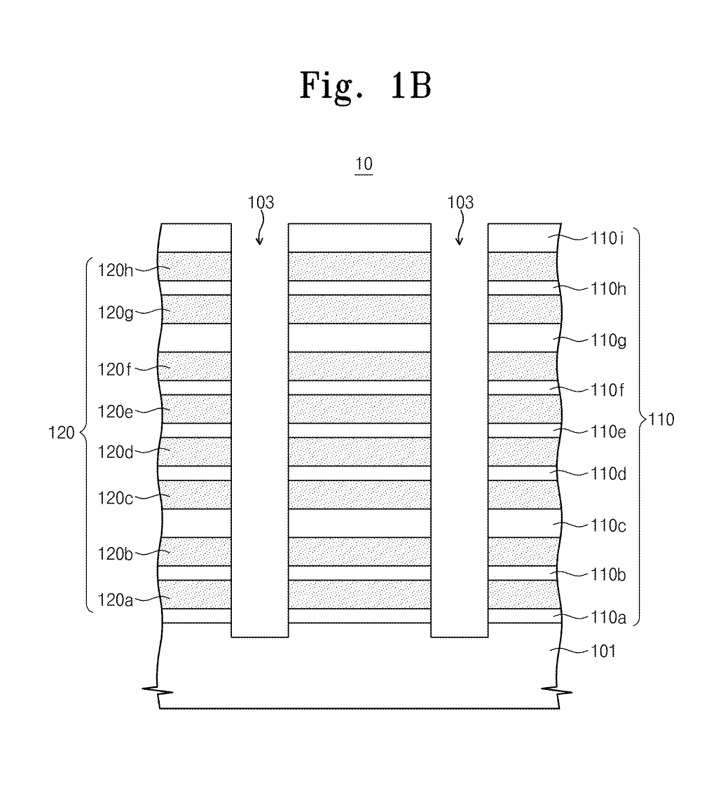

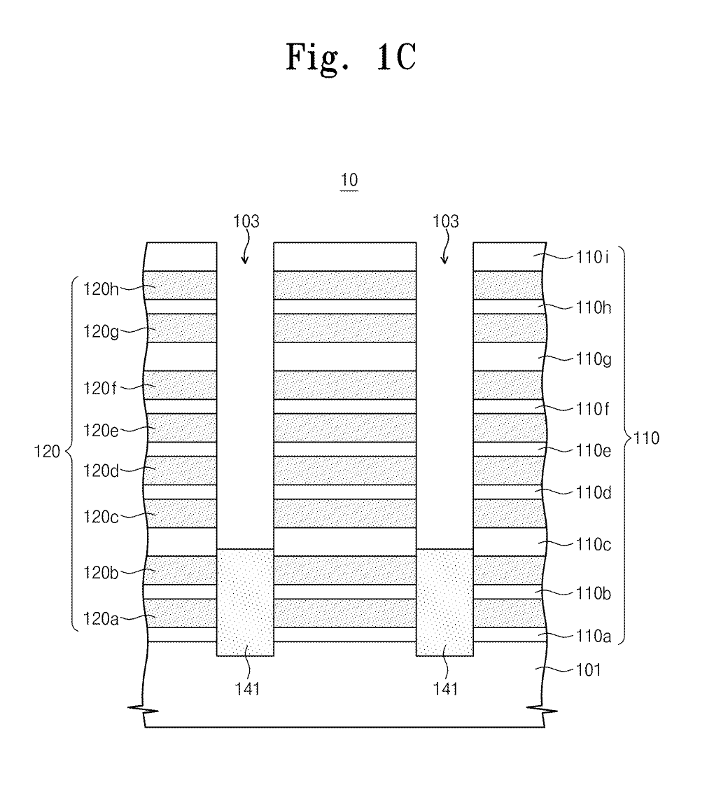

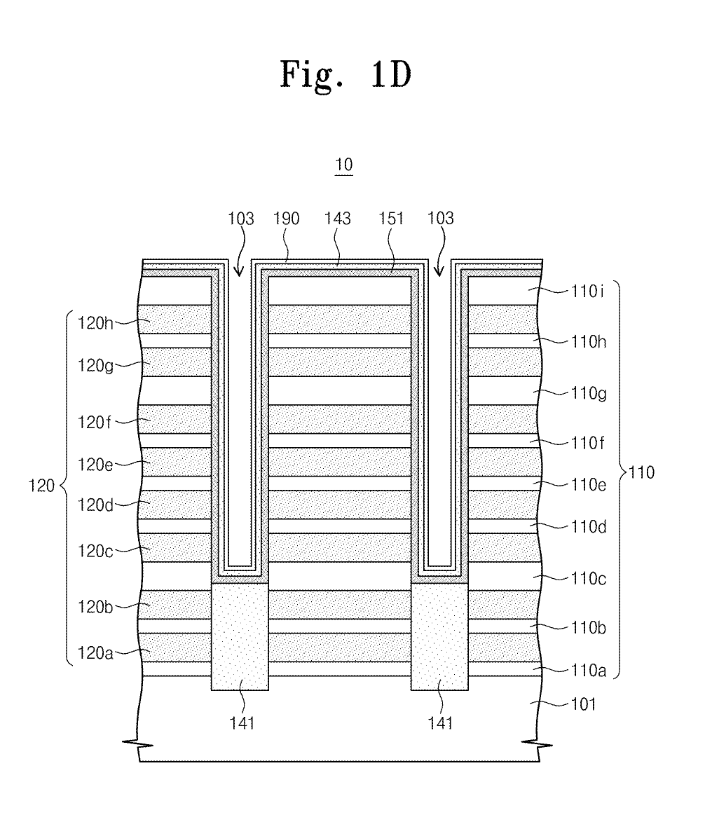

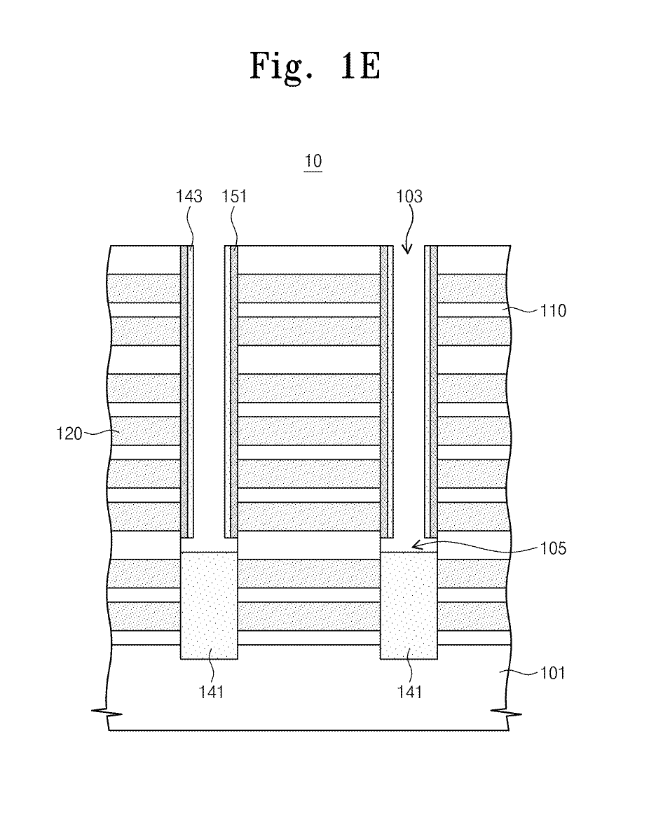

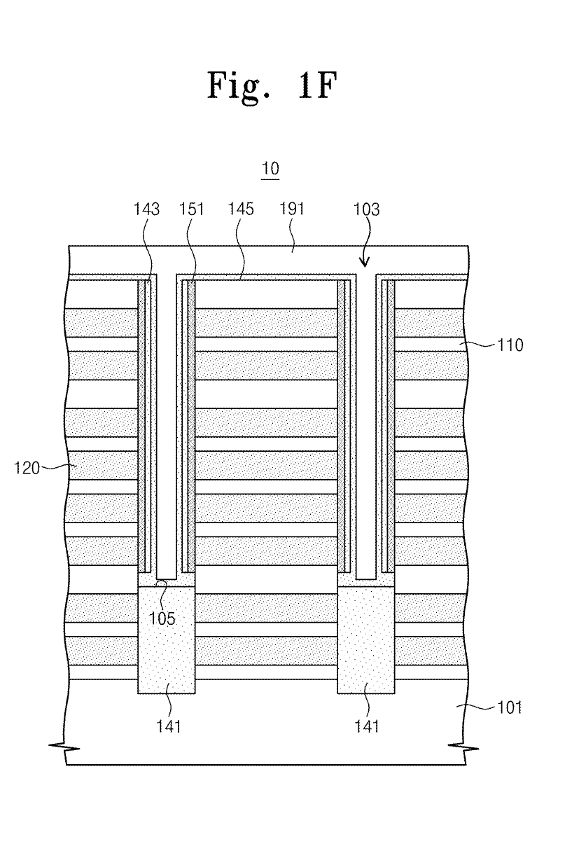

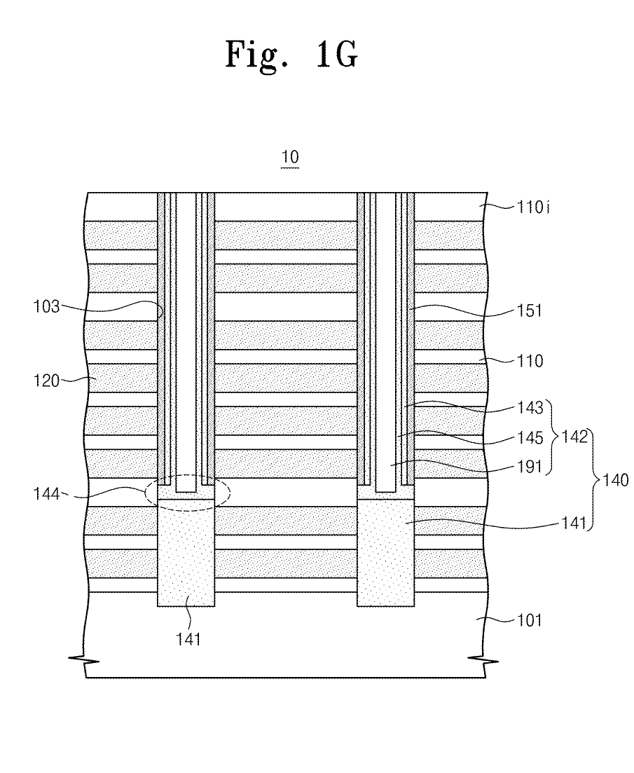

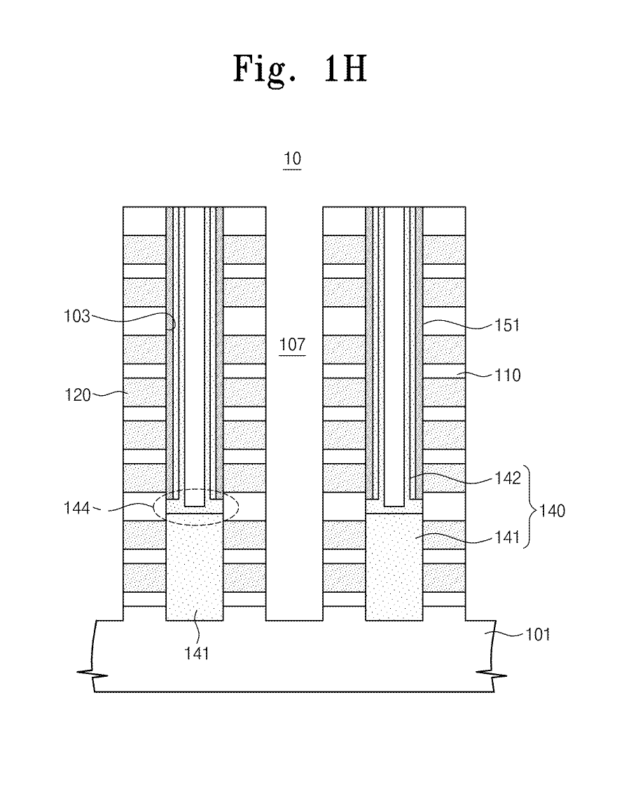

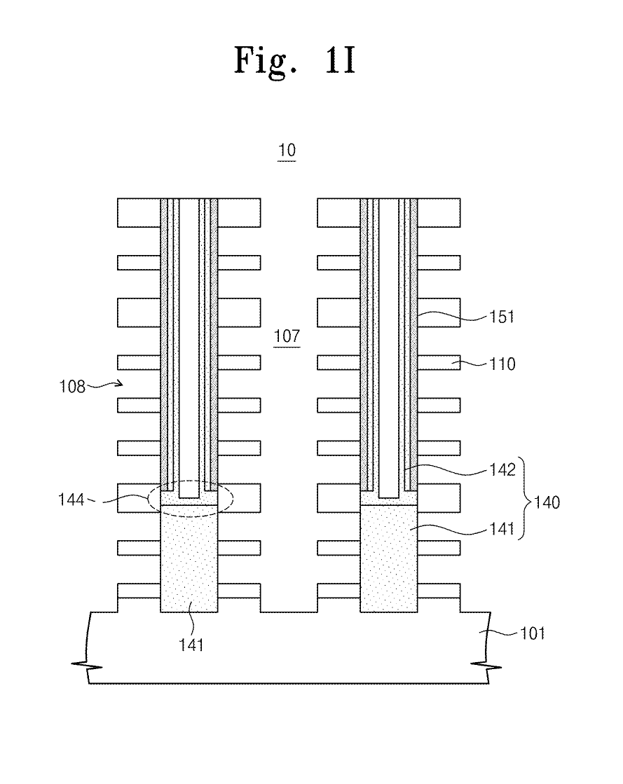

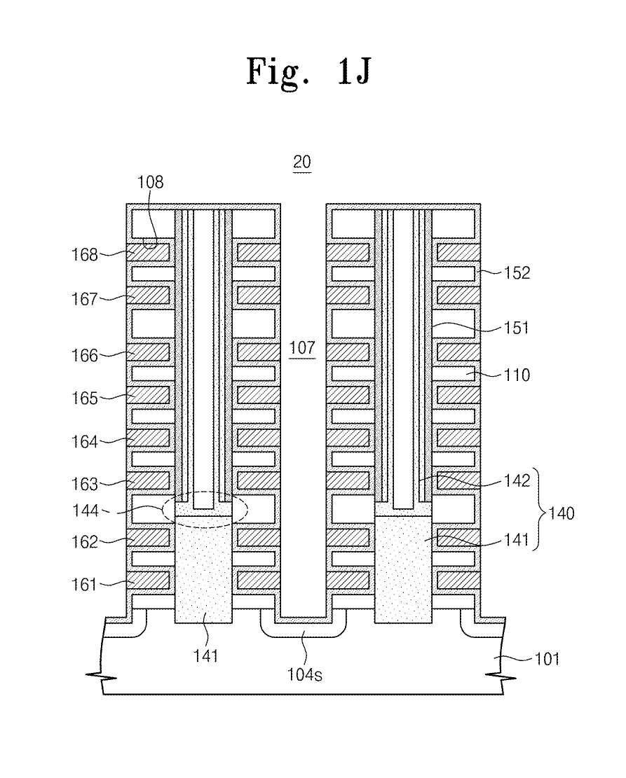

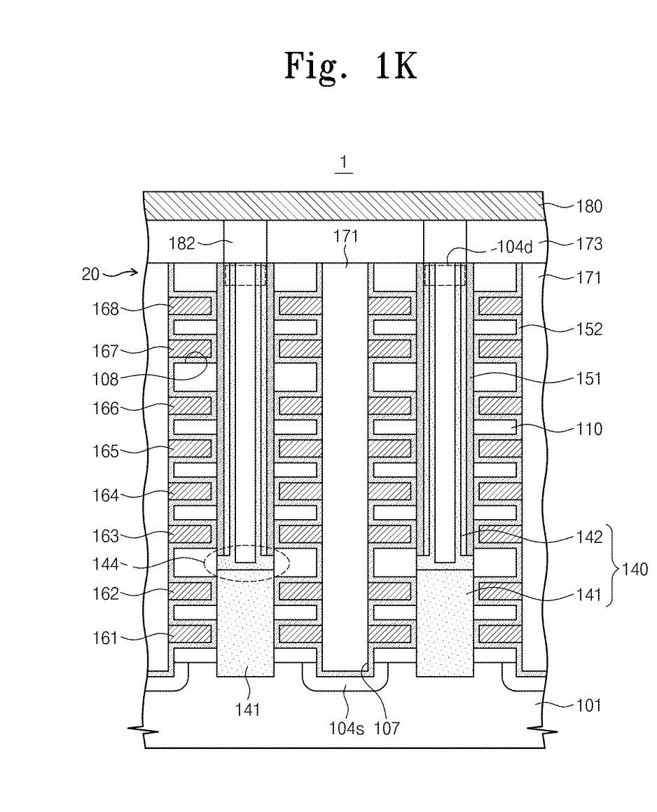

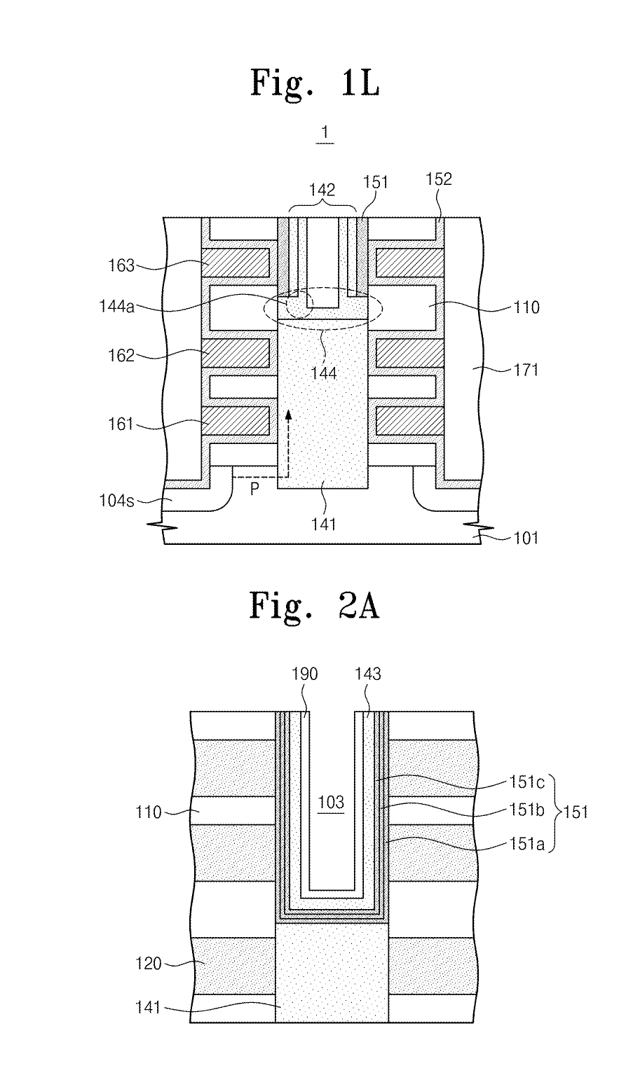

FIGS. 1A to 1K are cross-sectional views illustrating a method for fabricating a semiconductor memory device according to an embodiment of inventive concepts. FIG. 1L is an enlarged view of a portion of FIG. 1.

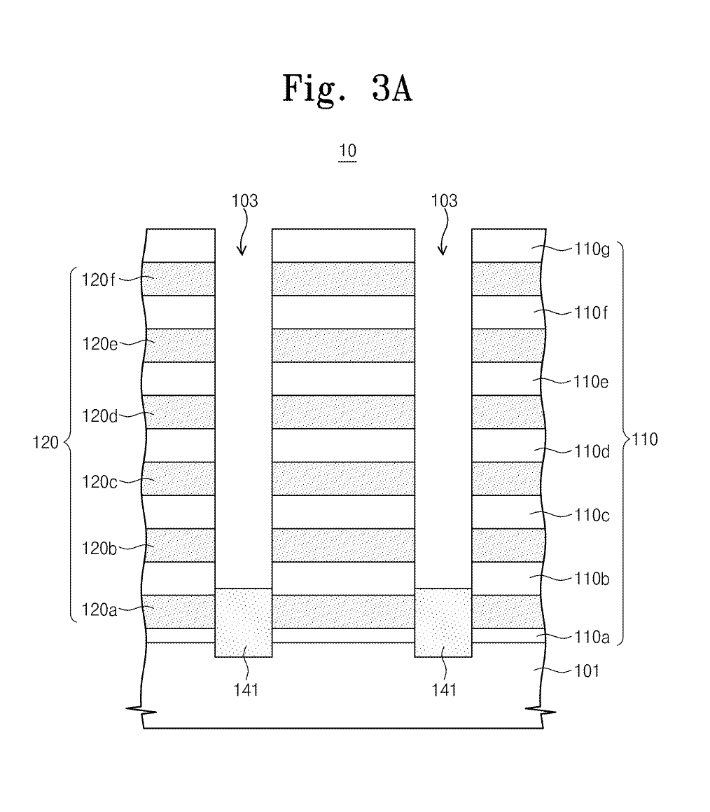

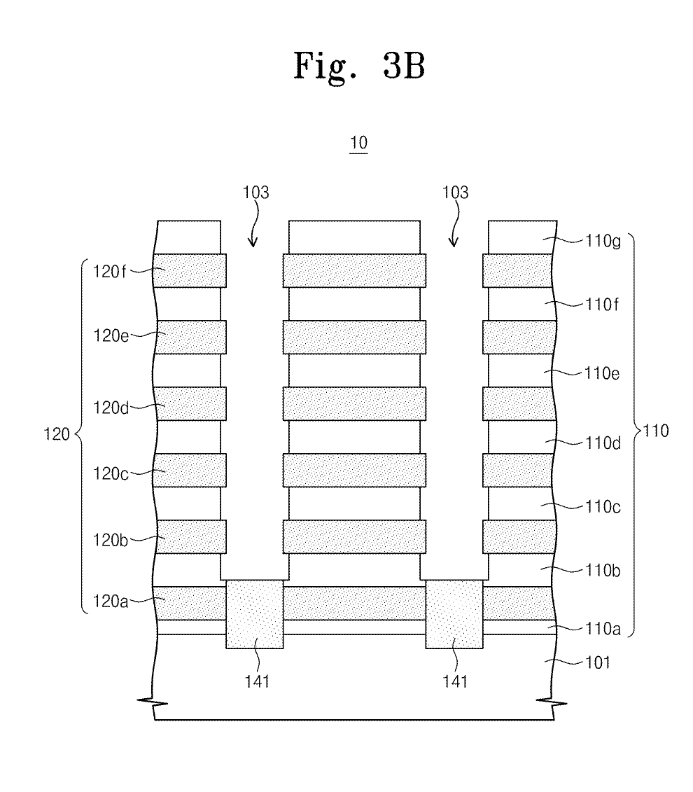

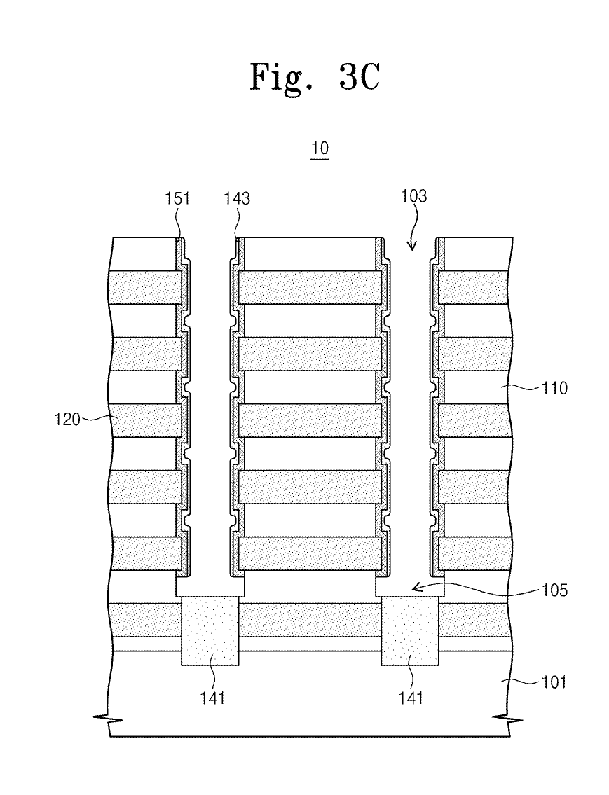

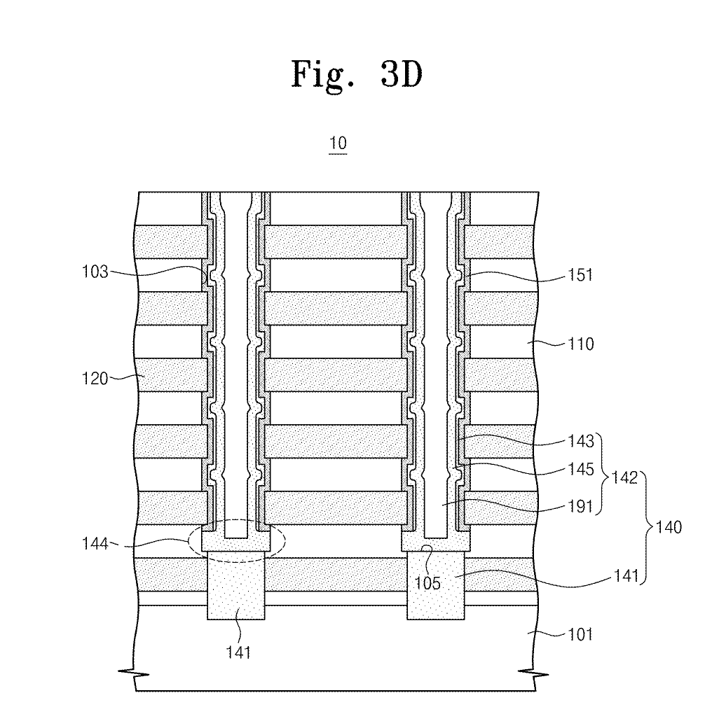

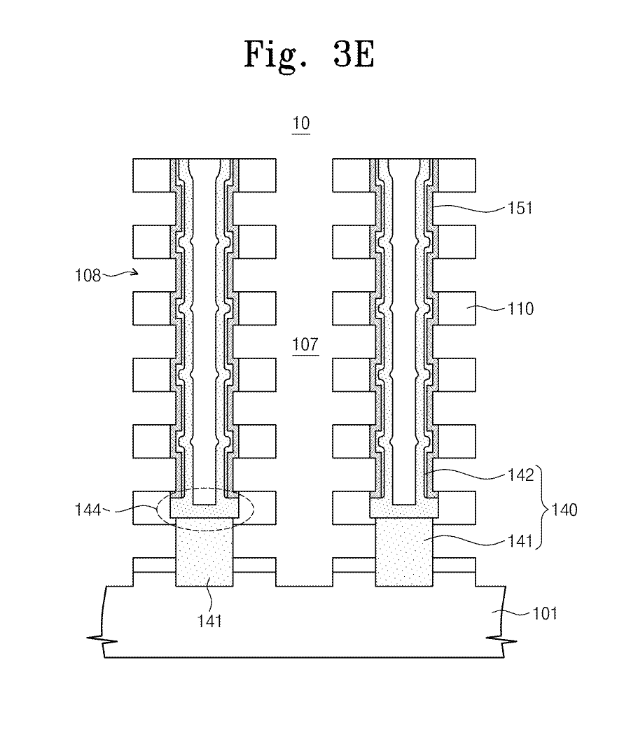

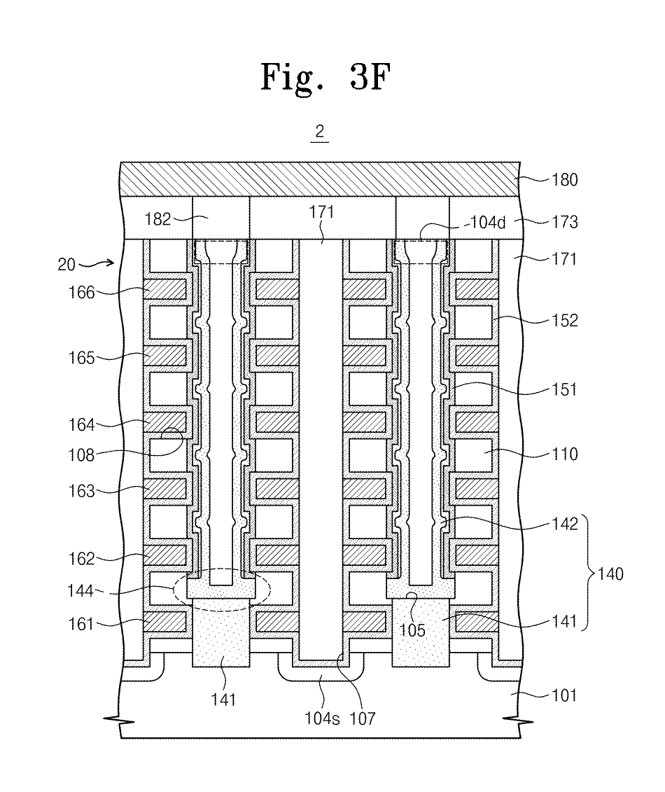

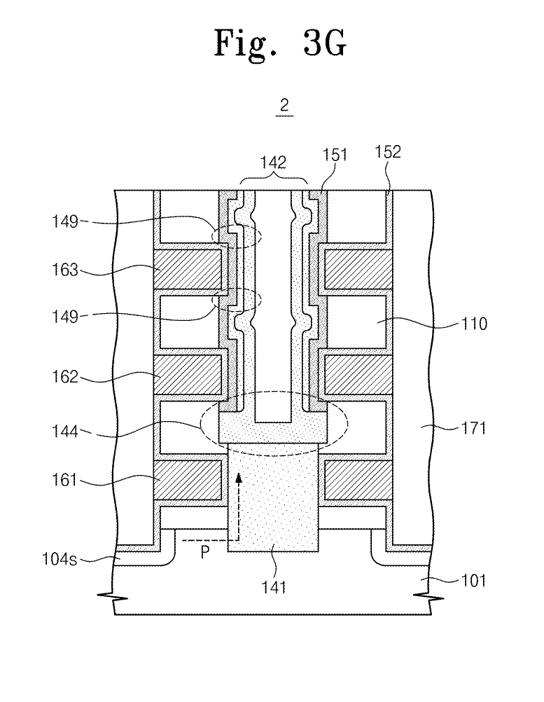

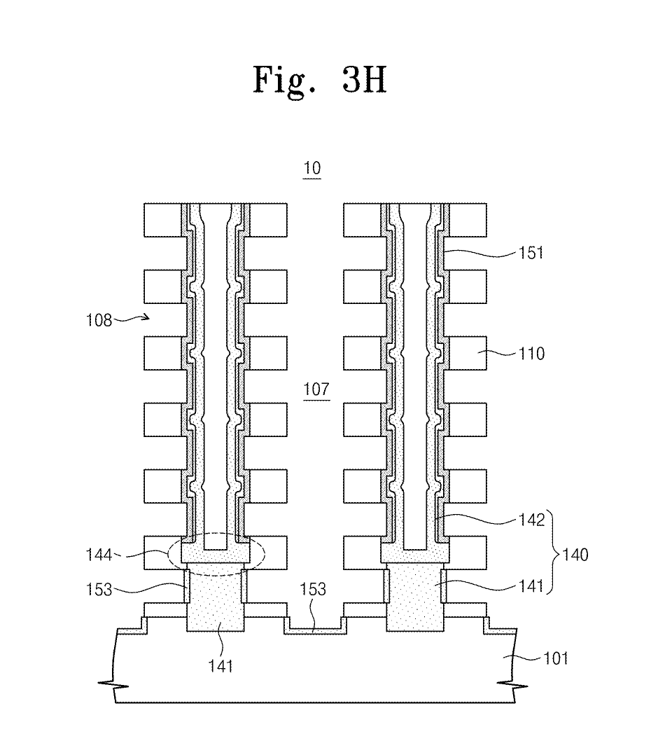

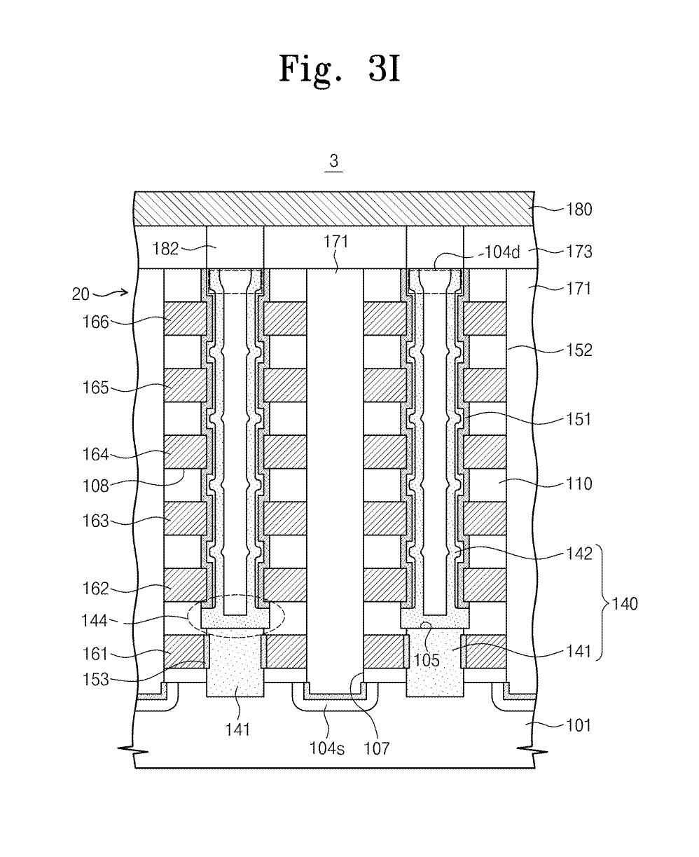

Referring to FIG. 1A, a mold stack 10 may be formed on a substrate 101. The substrate 101 may include a semiconductor substrate, for example a single-crystalline silicon wafer. The mold stack 10 may be formed by alternately and repeatedly stacking a plurality of insulating layers 110 and a plurality of sacrificial layers 120. The insulating layers 110 may be silicon oxide layers or silicon nitride layers. The sacrificial layers 120 may be formed of a material having an etch selectivity with respect to the insulating layers 110. The sacrificial layers 120 may be formed of one selected from a group consisting of silicon oxide, silicon nitride, silicon carbide, silicon, and silicon-germanium. The insulating layers 110 may be silicon oxide layers (e.g. SiOx) and the sacrificial layers 120 may be silicon nitride layers (e.g. SiNx), but example embodiments of inventive concepts are not limited thereto. Thicknesses of the sacrificial layers 120 may be substantially equal to each other. Thicknesses of the insulating layers 110 may be substantially equal to each other. Alternatively, one or some of thicknesses of the insulating layers 110 may be different from another or others of thicknesses of the insulating layers 110. For example, a third insulating layer 110c and a seventh insulating layer 110g of the insulating layers 110 may be relatively thicker. The number of stacked layers and the thicknesses of the insulating layers 110 shown in FIG. 1A are illustrated as an example. Alternatively, as illustrated in FIG. 3A, the insulating layers 110 may have thicknesses substantially equal or similar to each other. In FIG. 1A, lowercase letters of the English alphabet are added to the reference numeral 110, so that the insulating layers 110 are classified into first to ninth insulating layers 110a to 110i. Likewise, lowercase letters of the English alphabet are added to the reference numeral 120, so that the sacrificial layers 120 are classified into first and eighth sacrificial layers 120a to 120h.

Referring to FIG. 1B, the mold stack 10 may be patterned to form vertical channel holes 103. The vertical channel holes 103 may vertically penetrate the mold stack 10 to expose the substrate 101. For example, the vertical channel holes 103 may be formed by a dry etching process. The substrate 101 exposed by the vertical channel hole 103 may be recessed by an over etching. A width of the channel hole 103 may be uniform or changed according to a vertical depth thereof. For the purpose of ease and convenience in explanation, the following descriptions will be described using the channel hole 103 having a substantially uniform width as an example.

Referring to FIG. 1C, a lower channel 141 may be formed to partially fill the vertical channel 103. The lower channel 141 may be in contact with the substrate 101 and have a pillar shape. The lower channel 141 may be formed of a semiconductor having the same conductivity type as the substrate 101, or an intrinsic semiconductor. For example, the lower channel 141 may include P-type silicon or intrinsic silicon. The lower channel 141 may be formed of a poly-crystalline semiconductor by a deposition technique. Alternatively, the lower channel 141 may be formed of a single-crystalline semiconductor by an epitaxial growth process or a laser crystallization technique. According to example embodiments of inventive concepts, the lower channel 141 may be formed of single-crystalline P-type silicon or single-crystalline intrinsic silicon. The lower channel 141 may be in contact with sidewalls of the first sacrificial layer 120a and the second sacrificial layer 120b. Additionally, the lower channel 141 may also be in contact with a portion of a sidewall of the third insulating layer 110c.

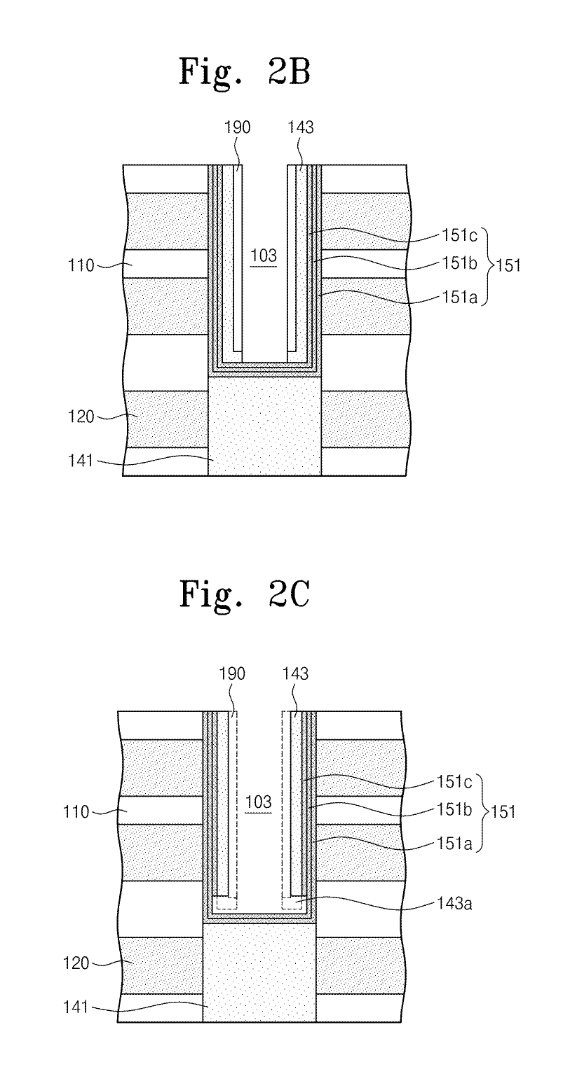

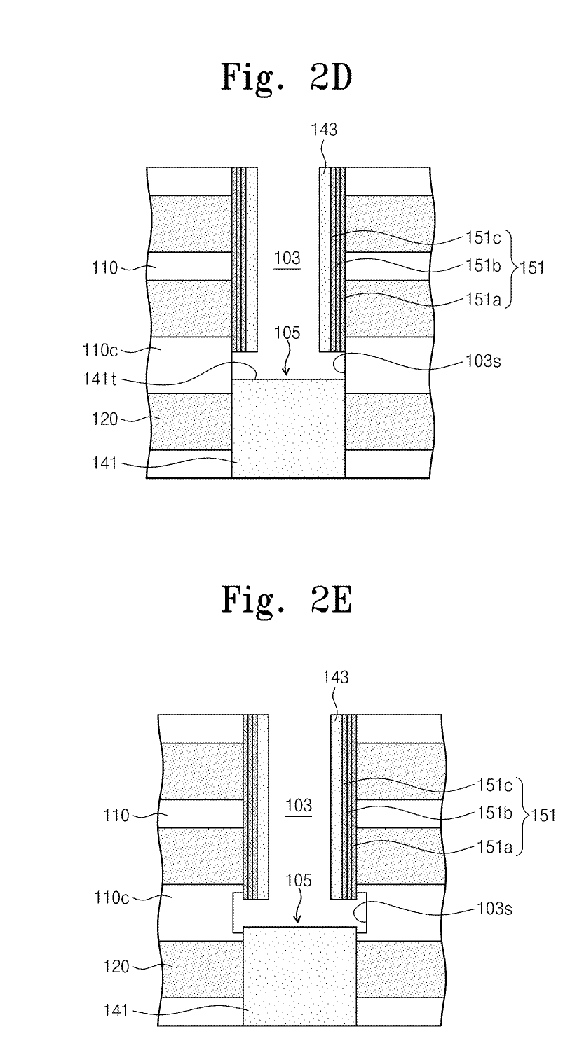

Referring to FIG. 1D, a first data storage layer 151 may be formed on the substrate 101. The first data storage layer 151 may extend along an inner sidewall of the vertical channel hole 103 to cover the mold stack 10. A first semiconductor layer 143 may be formed to cover the first data storage layer 151. The first data storage layer 151 may have a relatively thin thickness and be in contact with the lower channel 141. The first data storage layer 151 may be formed by a chemical vapor deposition (CVD) process or an atomic layer deposition (ALD) process. The first data storage layer 151 may be formed in a single-layer structure or a multi-layer structure. This will be described in more detail with reference to FIG. 2A later. The first semiconductor layer 143 may be formed of a semiconductor material (e.g. poly-crystalline or single-crystalline silicon) by a CVD process or an ALD process. An insulating material (e.g. SiOx) may be deposited to further form a spacer layer 190 covering the first semiconductor layer 143 and having a substantially thin thickness.

Referring to FIG. 1E, the spacer layer 190, the first semiconductor layer 143, and the first data storage layer 151 may be successively patterned. The first semiconductor layer 143 and the first data storage layer 151 may be formed to have vertical shapes confined on the inner sidewall of the vertical channel 141 due to the pattering process. The spacer layer 190 may be removed by the patterning process. Additionally, an opening 105 may be formed by the patterning process such that a top surface of the lower channel 141 may be completely exposed. The first data storage layer 151 may include a portion or all of a blocking insulating layer 151a, a trap insulating layer 151b, and a tunnel insulating layer 151c as illustrated in FIG. 2A. Forming the opening 105 by the patterning process will be described in more detail with reference to FIGS. 2A to 2E later.

Referring to FIG. 1F, a second semiconductor layer 145 and an insulating filling layer 191 may be sequentially formed. The second semiconductor layer 145 may partially or fully fill the opening 105. The second semiconductor layer 145 may have a cylinder shape which extends along the first semiconductor layer 143 to cover the mold stack 10. The insulating filling layer 191 may fill an inside of the cylinder shape and cover the second semiconductor layer 145. The second semiconductor layer 145 may be formed of the same material as or a similar material to the first semiconductor layer 143 by a CVD process or an ALD process. For example, the second semiconductor layer 145 may be formed by depositing poly-crystalline or single-crystalline silicon. The insulating filling layer 191 may be formed by depositing a silicon oxide layer or a silicon nitride layer. Before the insulating filling layer 191 is formed, a hydrogen annealing process may further be performed to cure crystal defects existing in at least one of the first semiconductor layer 143 and the second semiconductor layer 145.

Referring to FIG. 1G, a planarization process may be performed until the ninth insulating layer 110i is exposed. Thus, the second semiconductor layer 145 may be patterned to be formed in a cylinder shape confined in the vertical channel hole 103. And the insulating filling layer 191 may be patterned to be formed in a pillar shape filling an inside of the cylinder shape. The first semiconductor layer 141, the second semiconductor layer 145 and the insulating filling layer 191 may constitute an upper channel 142. The upper channel 142 may have a macaroni structure of which the second semiconductor layer 145 surrounds the insulating filling layer 191. The upper channel 142 of the macaroni structure may be in contact with the lower channel 141 of a bulk structure, thereby constituting a vertical channel 140. A body contact 144 may correspond to a bottom portion of the second semiconductor layer 145. The body contact 144 may be connected to the lower channel 141. The body contact 144 may have a pillar shape or a bulk shape. A thickness (i.e. a vertical length) of the body contact 144 may be substantially equal to or greater than a width (i.e. a horizontal length) of the second semiconductor layer 145. Thus, it is possible to realize a good contact between the lower channel 141 and the upper channel 142. Additionally, it is possible to prevent (and/or minimize) a cutting phenomenon of the vertical channel 140 caused by lack of a contact area between the lower channel 141 and the upper channel 142.

Referring to FIG. 1H, a trench 107 exposing the substrate 101 may be formed between the vertical channels 140. For example, the mold stack 10 may be dry-etched to from the trench 107 penetrating the mold stack 10. The substrate 101 under the trench 107 may be recessed by an over etching. Sidewalls of the sacrificial layers 120 and the insulating layers 110 may be exposed by the trench 107.

Referring to FIG. 1I, the sacrificial layers 120 may be selectively removed by providing an etchant through the trench 107. For example, if the sacrificial layers 120 are silicon nitride layers and the insulating layers 110 are silicon oxide layers, the etchant may include phosphoric acid (H₃PO₄). Recess regions 108, which expose the lower channel 141 and the first data storage layer 151, may be formed between the insulating layers 110 by the selective removal of the sacrificial layers 120.

Referring to FIG. 1J, a second data storage layer 152 may be conformally formed on the substrate 101 having the recess regions 108, and then gates 161 to 168 may be formed to fill the recess regions 108, respectively. Thus, a gate stack 20 including the gate electrodes 161 to 168 may be formed. The gates 161 to 168 may be vertically stacked to be spaced apart from each other due to the insulating layers 110. The second data storage layer 152 may have a single-layer structure or a multi-layer structure. The first data storage layer 151 may include the trap insulating layer and the tunnel insulating layer, and the second data storage layer 152 may include the blocking insulating layer. Alternatively, the first data storage layer 151 may include the tunnel insulating layer, and the second data storage layer 152 may include the blocking insulating layer and the trap insulating layer. Alternatively, the first data storage layer 151 may include the tunnel insulating layer, the trap insulating layer, and a portion of the blocking insulating layer, and the second data storage layer 152 may include the other portion of the blocking insulating layer. A conductive material such as doped silicon, metal, metal nitride, and/or metal silicide may be deposited, and then the conductive material outside the recess regions 108 may be removed to form the gates 161 to 168.

First and second gates 161 and 162 may be adjacent to the lower channel 141. Third to eighth gates 163 to 168 may be adjacent to the upper channel 142. The first gate 161 and the second gate 162 may be non-memory selection gates and correspond to lower selection lines (or ground selection lines). The third to sixth gates 163 to 166 may be memory gates and correspond to word lines. The seventh gate 167 and the eighth gate 168 may also be non-memory selection gates. The seventh and eighth gates 167 and 168 may correspond to upper selection lines (or string selection lines). Alternatively, the third to seventh gates 163 to 167 may correspond to the word lines, and the eighth gate 168 may correspond to the upper selection line.

Dopants may be injected into the substrate 101 exposed through the trench 107, thereby forming a common source 104s. The common source 104s may be doped with dopants of a conductivity type different from that of the substrate 101. For example, the substrate 101 may be doped with P-type dopants and the common source 104s may be doped with N-type dopants.

Referring to FIG. 1K, a filling insulating layer 171 may be formed to fill the trench 107. For example, an insulating material may be deposited to cover the gate stack 20 and then the insulating material may be planarized to form the filling insulating layer 171 filling the trench 107. An interlayer insulating layer 173 may be formed to cover the gate stack 20. A plug 182 connected to the vertical channel 140 may be formed to penetrate the interlayer insulating layer 173. A bit line 180 may be formed on the interlayer insulating layer 173. The bit line 180 may be in contact with the plug 182. Thus, the bit line 180 may be electrically connected to the vertical channel 140 through the plug 182. Before the interlayer dielectric layer 173 is formed, dopants may be injected into a top portion of the vertical channel 140 to form a drain 104d having the same conductivity type as the common source 104s. A three-dimensional (3D) semiconductor memory device 1 (e.g. a vertical NAND flash memory device) may be formed through the processes described above. The gates 161 to 168 may extend in a first horizontal direction on the substrate 101, and the bit line 180 may extend in a second horizontal direction substantially perpendicular to the first horizontal direction on the substrate 101. The gates 161 to 168 vertically stacked along the vertical channel 140 may constitute a cell string.

According to a semiconductor memory device 1 according to example embodiments of inventive concepts, as illustrated in FIG. 1L, the first data storage layer 151, which may lengthen a current path P, may be not formed between the common source 104s and the lower channel 141. Thus, it is possible to reduce (and/or minimize) the current path P between the common source 104s and the vertical channel 140. As a result, it is possible to reduce (and/or suppress) an increase of an electrical resistance caused by long current path P. As described with reference to FIGS. 2A to 2E later, since the first data storage layer 151 is patterned to have the vertical shape, it is possible to sufficiently secure a region 144a necessary for the current path P from the lower channel 141 to the upper channel 142. Thus, the body contact 144 may secure a sufficient space or path necessary for a current flow from the lower channel 141 toward the upper channel 142, or vice versa. As a result, a good current flow between the lower and upper channels 141 and 142 may be realized. The short current path and/or the good current flow may give improved electrical characteristic to the semiconductor memory device 1.

FIGS. 2A to 2D are cross-sectional views illustrating an example of methods for forming an opening in a semiconductor memory device according to an embodiment of inventive concepts. FIG. 2E is a cross-sectional view illustrating a modified embodiment of FIG. 2D.

Referring to FIG. 2A, the first data storage layer 151 may include the tunnel insulating layer 151c. The first data storage layer 151 may include the tunnel insulating layer 151c and the trap insulating layer 151b. The first data storage layer 151 may include the tunnel insulating layer 151c, the trap insulating layer 151b, and the blocking insulating layer 151a. For example, a silicon oxide layer, an aluminum oxide layer, and/or a hafnium oxide layer may be deposited on the inner surface of the channel hole 103 to form the blocking insulating layer 151a. A silicon nitride layer may be deposited on the blocking insulating layer 151a to form the trap insulating layer 151b. A silicon oxide layer may be deposited on the trap insulating layer 151b to form the tunnel insulating layer 151c. The first semiconductor layer 143 may be formed on the first data storage layer 151 as illustrated in FIG. 1D, and then the spacer layer 190 may be formed on the first semiconductor layer 143.

Referring to FIG. 2B, an etch-back process may be performed on the spacer layer 190 and the first semiconductor layer 143. The spacer layer 190 may be patterned to have a vertical wall shape covering the first semiconductor layer 143 by the etch-back process. A portion of the first semiconductor layer 143, which is not covered by the spacer layer 190 of the vertical wall shape, may be etched by the etch-back process to expose a portion of the tunnel insulating layer 151c.

Referring to FIG. 2C, the tunnel insulating layer 151c may be patterned to have a vertical shape by a wet etching process. If the spacer layer 190 may be formed of the same material as or a similar material (e.g. a silicon oxide layer) to the tunnel insulating layer 151c, the spacer layer 190 may be etched together with the insulating layer 151c. Thus, the spacer layer 190 may be removed. A portion of the trap insulating layer 151b may be exposed by the pattering of the tunnel insulating layer 151c. When the tunnel insulating layer 151c is etched, the first semiconductor layer 143 may not be etched, or a bottom portion 143a of the first semiconductor layer 143 may be etched to be partially or fully removed.

Referring to FIG. 2D, the trap insulating layer 151b and the blocking insulating layer 151a may be successively wet-etched or wet-etched together to be patterned. Thus, it is possible to form the first data storage layer 151 separated from the lower channel 141. If the spacer layer 190 of FIG. 2C is formed of the same material as or a similar material to the trap insulating layer 151b or the blocking insulating layer 151a, the spacer layer 190 may be etched together with the trap insulating layer 151b or the blocking insulating layer 150a, so that the spacer layer 190 may be removed. The bottom portion 143a of the first semiconductor layer 143 of FIG. 2C may be etched together with the trap insulating layer 151b or the blocking insulating layer 151a, so that the bottom portion 143a may be partially or completely removed. A portion of the first data storage layer 151 horizontally extending along a top surface 141t of the lower channel 141 may be removed, so that the first data storage layer 151 may be patterned in the vertical shape. At the same time, the opening 105 may be formed. The opening 105 may completely expose the top surface 141t of the lower channel 141. Additionally, the opening 105 may expose a sidewall 103s of the vertical channel hole 103 (e.g. a sidewall of the third insulating layer 110c). As illustrated in FIG. 2E, the sidewall 103s of the vertical channel hole 103 (e.g. the sidewall of the third insulating layer 110c) may be etched during the wet etching of the tunnel insulating layer 151c, so that the opening 105 may become enlarged.

FIGS. 3A to 3F are cross-sectional views illustrating a method for fabricating a semiconductor memory device according to example embodiments of inventive concepts. FIG. 3G is an enlarged view of a portion of FIG. 3F. FIGS. 3H and 3I are cross-sectional views illustrating steps of a method for fabricating a semiconductor memory device according to example embodiments of inventive concepts.

Referring to FIG. 3A, a mold stack 10 may be formed on a substrate 101, and then the mold stack 10 may be patterned to form vertical channel holes 103 exposing the substrate 101. The mold stack 10 may be formed by alternately stacking first to seventh insulating layers 110a to 110g and first to sixth sacrificial layers 120a to 120f. The first to sixth sacrificial layers 120a to 120f may include silicon nitride layers having thicknesses substantially equal to or similar to each other, respectively. The first to seventh insulating layers 110a to 110g may include silicon oxide layers, respectively. Each of the second to seventh insulating layers 110b to 110g may be thicker than the first insulating layer 110a. The second to seventh insulating layers 110b to 110g may have thicknesses substantially equal to or similar to each other, respectively. The substrate 101 exposed the vertical channel hole 103 may be recessed by an over etching when the vertical channel hole 103 is formed. A lower channel 141 may be formed to partially fill the vertical channel hole 103 and to be in contact with the substrate 101. The lower channel 141 may be formed of semiconductor (e.g. a single-crystalline semiconductor) by using an epitaxial growth process or a laser crystallization technique. The lower channel 141 may be in contact with the first sacrificial layer 120a and a portion of the second insulating layer 110b.

Referring to FIG. 3B, the second to seventh insulating layers 110b to 110g exposed by the vertical channel 103 may be laterally recessed. The second to seventh insulating layers 110b to 110g may be etched to be recessed when a cleaning process removing contaminators is performed by a cleaning solution including hydrofluoric acid (HF), ammonia (NH₃), hydrochloric acid (HCl), or sulfuric acid (H₂SO₄). Alternatively, the second to seventh insulating layers 110b to 110g may be recessed by a wet etching process using an etchant. The vertical channel hole 103 may have an uneven inner sidewall due to the cleaning or wet etching process. Alternatively, before the lower channel 141 is formed, the first to seventh insulating layers 110a to 110g may be recessed by the cleaning or wet etching process. Thus, a sidewall of the lower channel 141 may be uneven.

Referring to FIG. 3C, a first data storage layer 151 and a first semiconductor layer 143 may be formed to vertically extend along the inner sidewall of the vertical channel hole 103. The first data storage layer 151 and the first semiconductor layer 143 may be formed unevenly along the inner sidewall of the vertical channel hole 103. The first data storage layer 151 and the first semiconductor layer 143 may be formed by the processes described with reference to FIGS. 2A to 2E. Thus, an opening 105 may be formed to completely expose a top surface of the lower channel 141.

Referring to FIG. 3D, a second semiconductor layer 145 may be formed to partially or fully fill the opening 105. The second semiconductor layer 145 may have a cylinder shape which vertically extends along the first semiconductor layer 143. A filling layer 191 may be formed to cover the second semiconductor layer 145 and to fill the vertical channel hole 103. The first semiconductor layer 143, the second semiconductor layer 145, and the filling layer 191 may constitute an upper channel 142 having a macaroni structure. The upper channel 142 may be in contact with the lower channel 141 to constitute a vertical channel 140. A body contact 144, which corresponds to a bottom portion of the second semiconductor layer 145, may be a pillar or bulk shape having a width greater than a width of the lower channel 141. At least one of the upper channel 142 and the first data storage layer 151 may have an uneven shape along the uneven (or non-uniform) inner sidewall of the vertical channel hole 103.

Referring to FIG. 3E, the mold stack 10 may be patterned to form a trench 107 between the vertical channel holes 140, and then an etchant may be provided through the trench 107, thereby selectively removing the sacrificial layers 120. The substrate 101 exposed through the trench 107 may be recessed by an over etching. Recess regions 108, which expose the lower channel 141 and the first data storage layer 151, may be formed between the insulating layers 110 by the selective removal of the sacrificial layers 120.

After the recess regions 108 are formed, a second data storage layer 152 may be formed as described with reference to FIGS. 3F and 3G. Alternatively, after the recess regions 108 are formed, a sidewall of the lower channel 141 may be oxidized to form a gate insulating layer 153 as described with reference to FIGS. 3H and 3I.

Referring to FIG. 3F, the second data storage layer 152 and gates 161 to 166 may be formed in the recess regions 108 by the same processes as or similar processes to the processes described with reference to FIGS. 1J and 1K, thereby forming a gate stack 20. Dopants may be injected into the substrate 101 through the trench 107, thereby forming a common source 104s. The trench 107 may be filled with a filling insulating layer 171. Dopants may be injected into a top portion of the vertical channel 140 to form a drain 104d. An interlayer insulating layer 173 may be formed on the gate stack 20. A plug 182 may be formed to penetrate the interlayer insulating layer 173. A bit line 180 may be formed on the interlayer insulating layer 173. The bit line 180 may be electrically connected to the vertical channel 140 through the plug 182. Thus, a semiconductor memory device 2 may be formed.

A first gate 161 of the gates 161 to 166 may be adjacent to the lower channel 141 and be a non-memory gate. The first gate 161 may correspond to a lower selection line (or a ground selection line). Second to fifth gates 162 to 165 may be memory gates and correspond to word lines. A sixth gate 166 may be a non-memory gate and correspond to an upper selection line (or a string selection line). According to example embodiments of inventive concepts, the second to fourth gates 162 to 164 may correspond to the word lines and the fifth and sixth gates 165 and 166 may correspond to the upper selection lines.

Referring to FIGS. 3F and 3G, according to example embodiments of inventive concepts, the semiconductor memory device 2 may have a short current path P between the common source 104s and the lower channel 141. The body contact 144 may have the pillar or bulk shape having the width greater than the width of the lower channel 141. Additionally, the second to sixth gates 162 to 166 may protrude toward the first data storage layer 151, and the upper channel 142 may be bent at the protruding portions of the gates 162 to 166. An electric field may be focused at the bent portion 149. A mobility of carriers may be improved by the focused electric field.

Referring to FIG. 3H, according to example embodiments of inventive concepts, the sidewall of the lower channel 141 exposed by the recess region 108 may be oxidized to form a gate insulating layer 153 surrounding the lower channel 141. The first data storage layer 151 may include all of the tunnel insulating layer, the trap insulating layer, and the blocking insulating layer. The gate insulating layer 153 may be formed by a thermal treatment process which selectively oxidizes the exposed sidewall of the lower channel 141 in a gas atmosphere including oxygen. The gate insulating layer 153 may be formed through a reaction between silicon consisting of the lower channel 141 and oxygen during the thermal treatment process. Thus, a portion of the lower channel 141 may be consumed. Even though the first data storage layer 151 is exposed by the recess regions 108, since the first data storage layer 151 may be formed of an insulating material, the gate insulating layer 153 may not be formed on a sidewall of the first data storage layer 151. The gate insulating layer 153 may also be formed on the substrate 101 exposed through the trench 107.

Referring to FIG. 3I, the recess regions 108 may be filled with a conductive material, thereby forming the gates 161 to 166. Thus, the gate stack 20 may be formed. After the common source 104s is formed in the substrate 101 exposed by the trench 107, the filling insulating layer 171 may be formed to fill the trench 107. Dopants may be injected into a top end portion of the vertical channel 140, thereby forming the drain 104d, and then the insulating layer 173 may be formed on the gate stack 20. The plug 182 may be formed to penetrate the interlayer insulating layer 173, and then the bit line 180 may be formed on the interlayer insulating layer 173. The bit line 180 may be electrically connected to the vertical channel 140 through the plug 182. Thus, a semiconductor memory 3 may be realized.

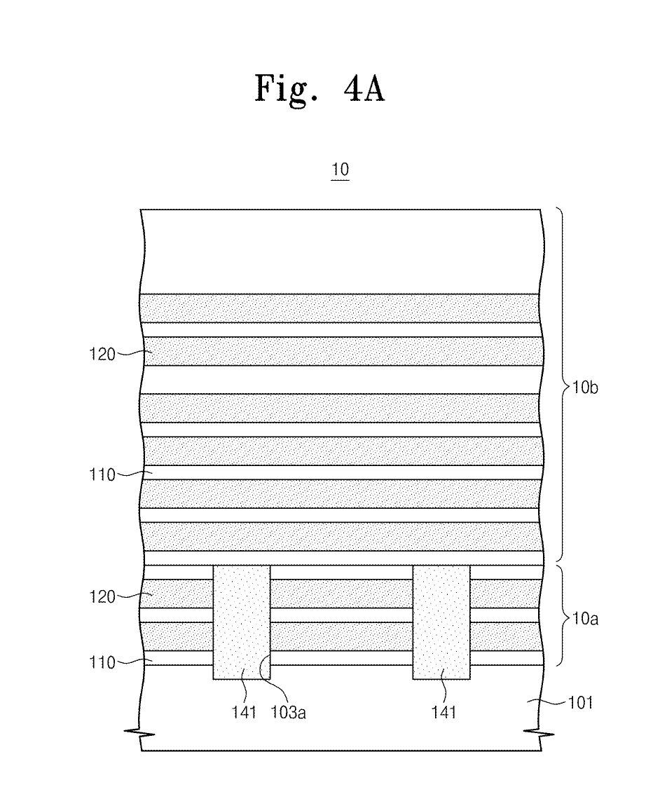

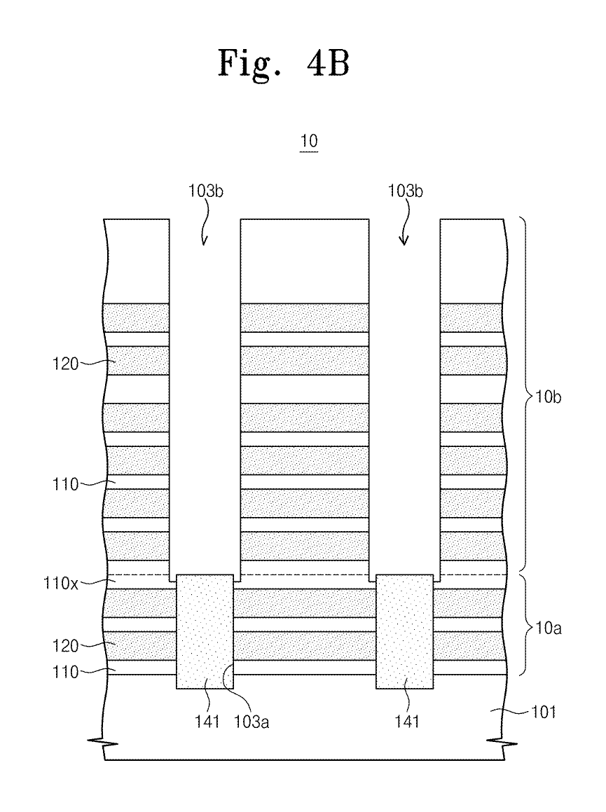

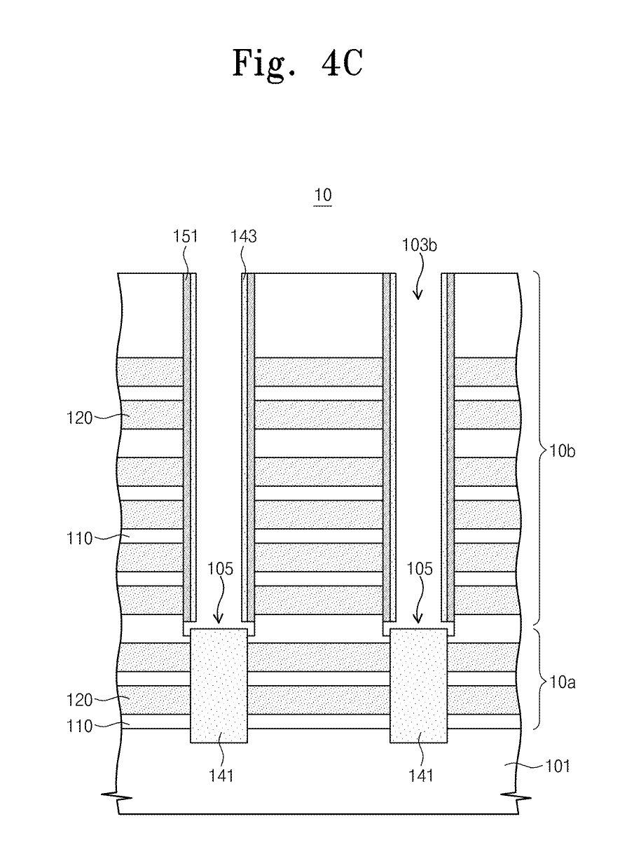

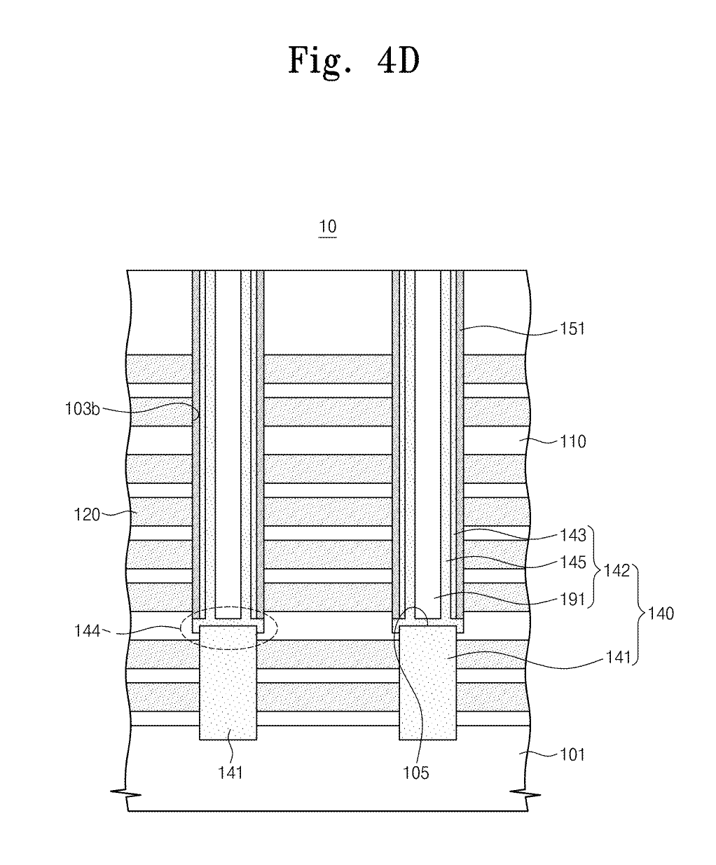

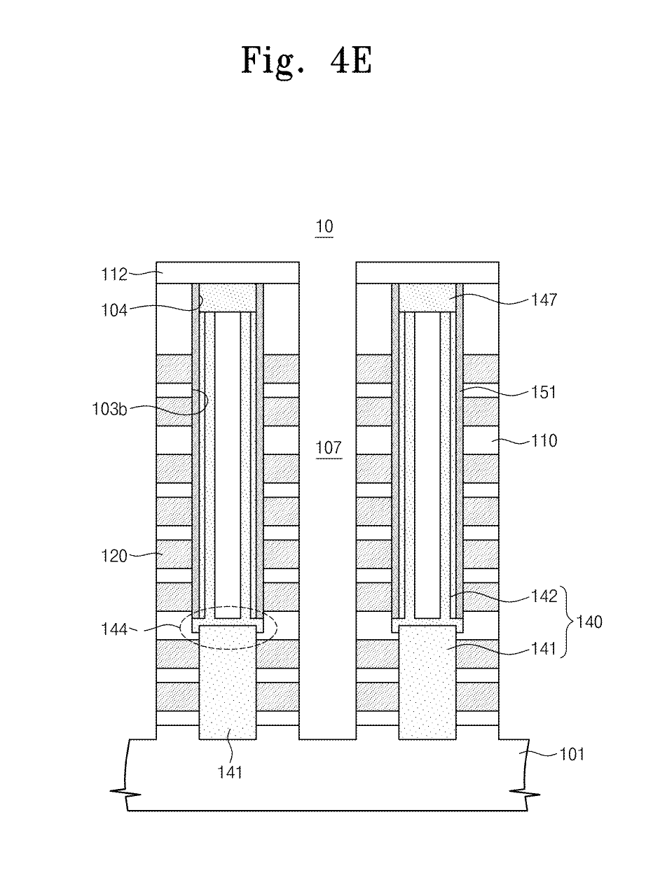

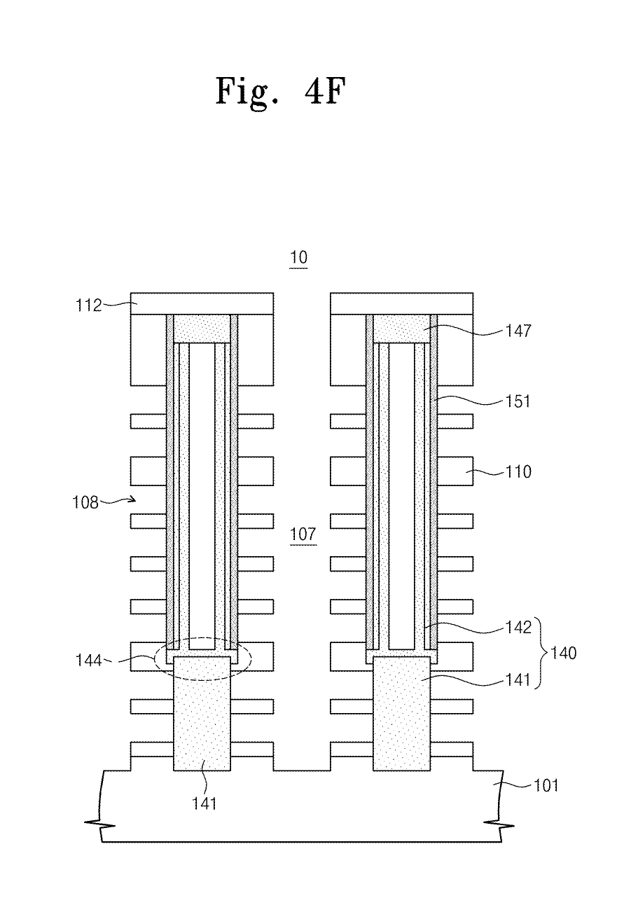

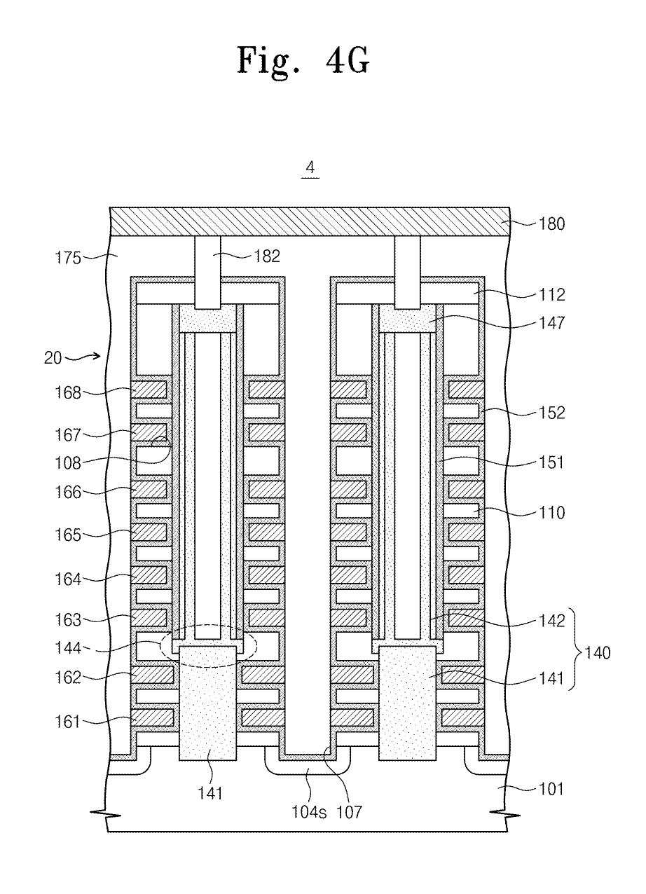

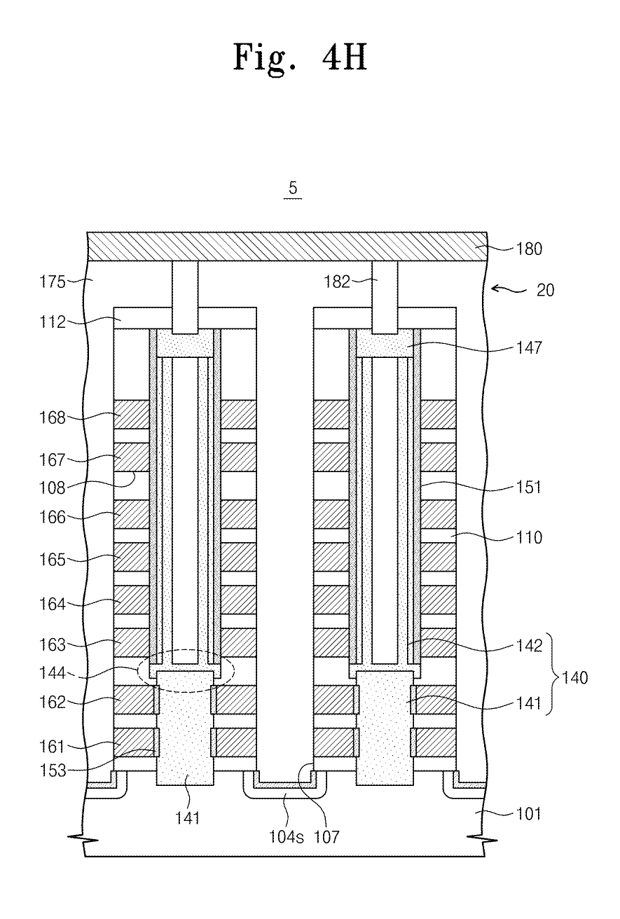

FIGS. 4A to 4G are cross-sectional views illustrating a method for fabricating a semiconductor memory device according to example embodiments of inventive concepts. FIG. 4H is a cross-sectional view illustrating a step of a method of fabricating a semiconductor device according to example embodiments of inventive concepts.

Referring to FIG. 4A, a mold stack 10 including a first stack 10a and a second stack 10b may be formed on a substrate 101. Lower channels 141 may be formed in the first stack 10a, and the second stack 10b may be stacked on the first stack 10a. For example, three insulating layers 110 and two sacrificial layers 120 may be alternately stacked on the substrate 101 to form the first stack 10a, and then first vertical channel holes 103a may be formed to penetrate the first stack 10a. The lower channels 141 may be formed in the first vertical channel holes 103a, respectively. The first channel 141 may fill the first vertical channel hole 103a and be in contact with the substrate 101. The first channel 141 may be composed of single-crystalline silicon. For example, seven insulating layers 110 and six sacrificial layers 120 may be alternately stacked on the first stack 10a, thereby forming the second stack 10b. In the first stack 10a, the number of the insulating layers 110 and the sacrificial layers 120 is described as an example. Likewise, in the second stack 10b, the number of the insulating layers 110 and the sacrificial layers 120 is described as an example. That is, example embodiments of inventive concepts are not limited to the number of the insulating layers 110 and the sacrificial layers 120. The method of forming the mold stack 10 including the lower channel 141 according to example embodiments of inventive concepts, as shown in FIGS. 4A-4G, may be applied to other methods according to example embodiments of inventive concepts illustrated in the specification.

Referring to FIG. 4B, the mold stack 10 may be patterned by a dry etching process to form a second vertical channel hole 103b penetrating the mold stack 10. The second vertical channel hole 103b may be vertically aligned with the first vertical channel hole 103a. The second vertical channel hole 103b may have a width greater than or identical to a width of the first vertical channel hole 103a. The second vertical channel hole 103b may expose the lower channel 141. When the second vertical channel hole 103 is formed, the uppermost insulating layer 110x of the first stack 10a may be recessed, so that the lower channel 141 may upward protrude over the recessed insulating layer 110x. Alternatively, the lower channel 141 may be recessed not to protrude. The second vertical channel hole 103b may have a smooth inner sidewall as illustrated in FIG. 4B. Alternatively, the inner sidewall of the second vertical channel hole 103b may be uneven as illustrated in FIG. 3B.

Referring to FIG. 4C, a first data storage layer 151 and a first semiconductor layer 143 may be formed to vertically extend along the inner sidewall of the second vertical channel hole 103b. The first data storage layer 151 and the first semiconductor layer 143 may have a profile extending along the inner sidewall of the second channel hole 103b. According to example embodiments of inventive concepts, the first data storage layer 151 and the first semiconductor layer 143 may have vertically straight shapes. Alternatively, the first data storage layer 151 and the first semiconductor layer 143 may have uneven shapes as illustrated in FIG. 3C. The first data storage layer 151 and the first semiconductor layer 143 may be formed by the processes described with reference to FIGS. 2A to 2E. Thus, an opening 105 may be formed to expose a top surface and a portion of a sidewall of the lower channel 141.

Referring to FIG. 4D, a second semiconductor layer 145 and a filling layer 191 may be formed. The second semiconductor layer 145 may partially or fully fill the opening 105. The second semiconductor layer 145 may have a cylinder shape vertically extending along the first semiconductor layer 143. The filling layer 191 may fill the second vertical channel hole 103b. The first semiconductor layer 143, the second semiconductor layer 145, and the filling layer 191 may constitute an upper channel 142 having a macaroni structure. The upper channel 142 may be connected to the lower channel 141 to constitute a vertical channel 140. A body contact 144 corresponding to a bottom portion of the second semiconductor layer 145 may have a width greater than the width of the lower channel 141. The body contact 144 may have a pillar or bottle cap shape which caps the top surface of the lower channel 141 and wraps a top portion of the lower channel 141.

Referring to FIG. 4E, a trench 107 may be formed between the vertical channels 140. After forming a capping insulating layer 112 on the mold stack 10 with a silicon oxide layer or a silicon nitride layer, the mold stack 10 may be patterned using the capping insulating layer 112 as an etch mask by a dry etching process, thereby forming the trench 107 exposing the substrate 101. Before the capping insulating layer 112 is formed, a third semiconductor layer 147 may be formed to be in contact with the vertical channel 140. A top end portion of the vertical channel 140 may be removed to form a hole 104 and then the hole 104 may be filled with semiconductor, so that the third semiconductor layer 147 may be formed. The third semiconductor layer 147 may be doped with dopants (e.g. N-type dopants) of a conductivity type different from the conductivity type of the dopants (e.g. P-type dopants) doped in the substrate 101. The third semiconductor layer 147 may function as a drain. The third semiconductor layer 147 may be doped by an ion implantation process or an in-situ method.

Referring to FIG. 4F, an etchant may be provided through the trench 107 to selective remove the sacrificial layers 120. Thus, recess regions 108 may be formed. After the recess regions 108 are formed, a second data storage layer 152 may be formed as described with reference to FIG. 4G, or a sidewall of the lower channel 141 may be oxidized to form a gate insulating layer 153 as described with reference to FIG. 4H.

As illustrated in FIG. 4G, according to example embodiments of inventive concepts, the recess regions 108 may be filled with a second data storage layer 152 and gates 161 to 168, thereby forming a gate stack 20. Dopants may be injected into the substrate 101 exposed through the trench 107 to form a common source 104s. A filling insulating layer 175 may be formed to fill the trench 107 and to cover the gate stack 20. A plug 182 may be formed to be in contact with the third semiconductor layer 147. A bit line 180 electrically connected to the plug 182 may be formed on the filling insulating layer 175, thereby forming a semiconductor memory device 4. First and second gates 161 and 162 of the gates 161 to 168 may correspond to lower selection gates, third to sixth gates 163 to 166 may correspond to memory gates, and seventh and eighth gates 167 and 168 may correspond to upper selection gates.

As illustrated in FIG. 4H, according to example embodiments of inventive concepts, a sidewall of the lower channel 141 exposed through recess regions 108 may be oxidized by a thermal treatment process to form a gate insulating layer 153 surrounding the sidewall of the lower channel 141. The gate insulating layer 153 may also be formed on a top surface of the substrate 101 exposed by the trench 107. The first data storage layer 151 may include all of the tunnel insulating layer, the trap insulating layer, and the blocking insulating layer. Gates 161 to 168 filling the recess regions 108 may be formed to form a gate stack 20. Dopants may be injected into the substrate 101 exposed through the trench 107 to form the common source 104s. The filling insulating layer 175 may be formed to fill the trench 107 and to cover the gate stack 20. The plug 182 may be formed to be in contact with the third semiconductor layer 147. The bit line 180 electrically connected to the plug 182 may be formed on the filling insulating layer 175, thereby forming a semiconductor memory device 5.

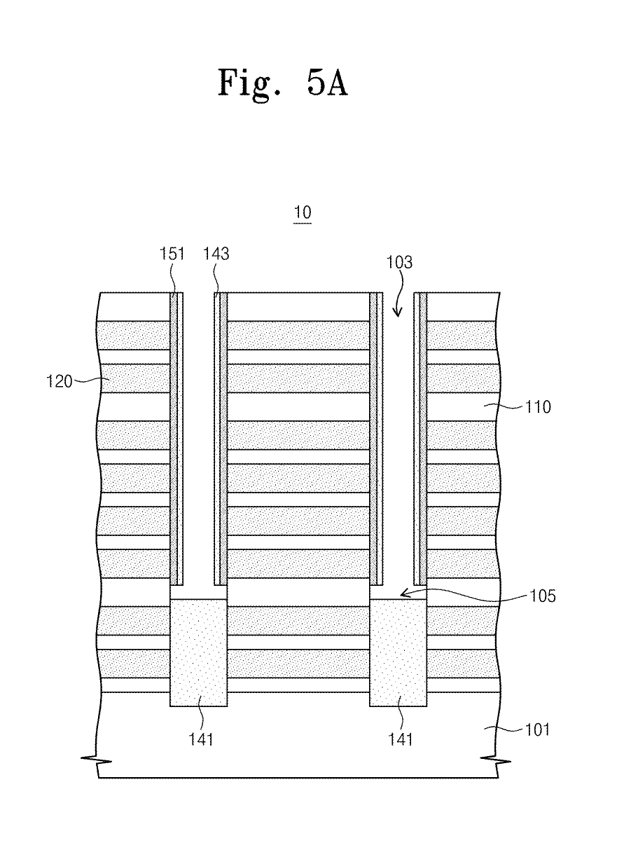

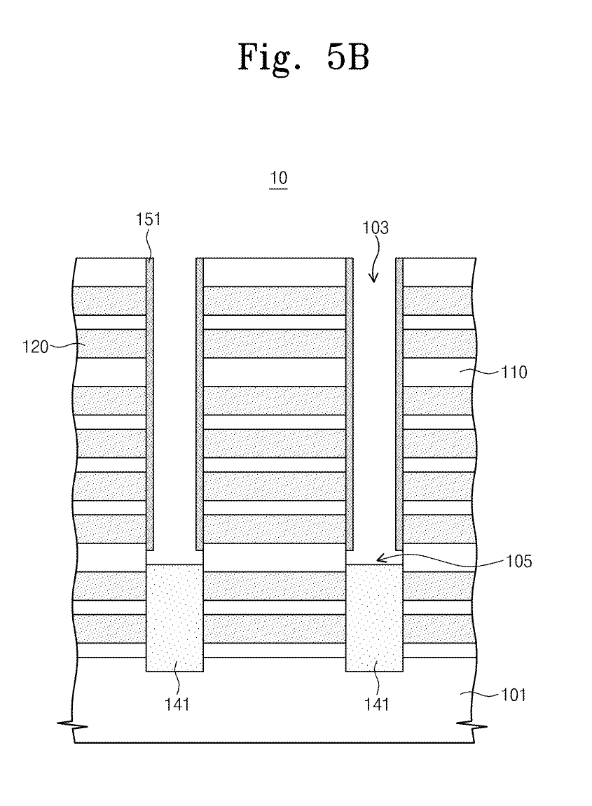

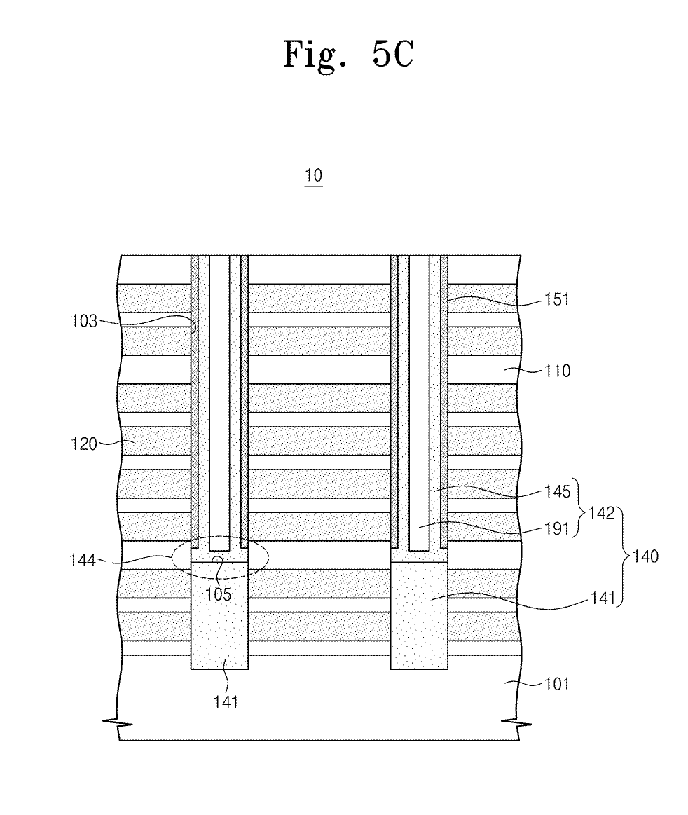

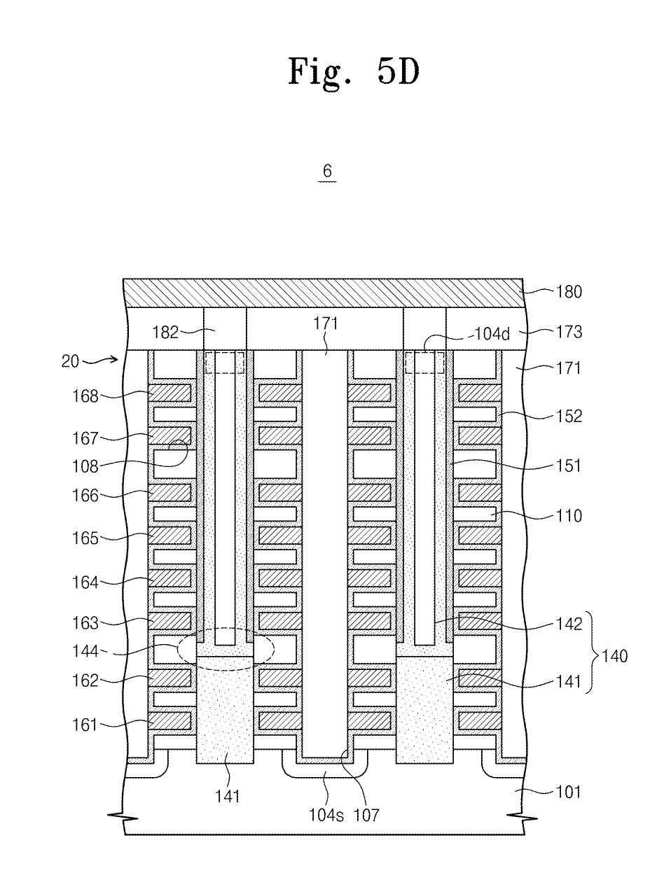

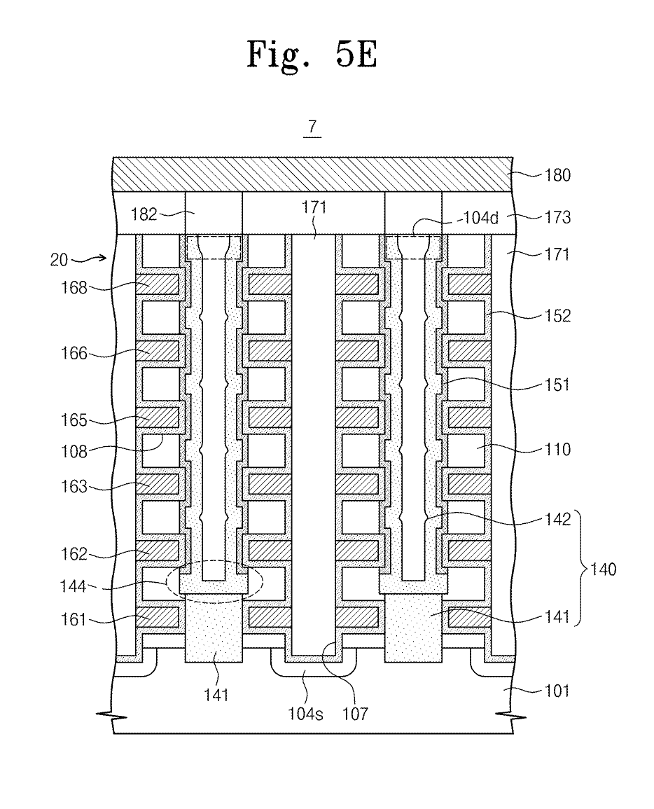

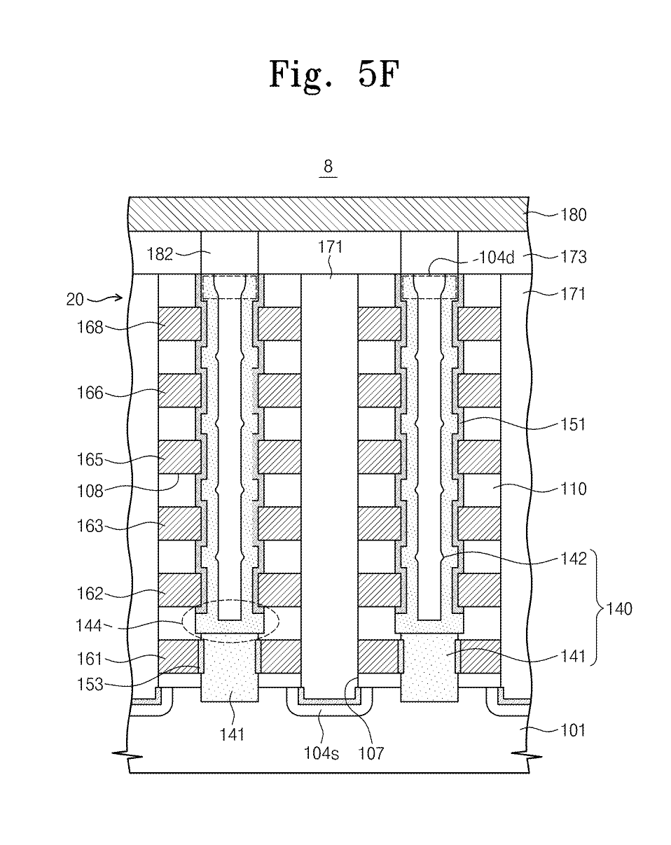

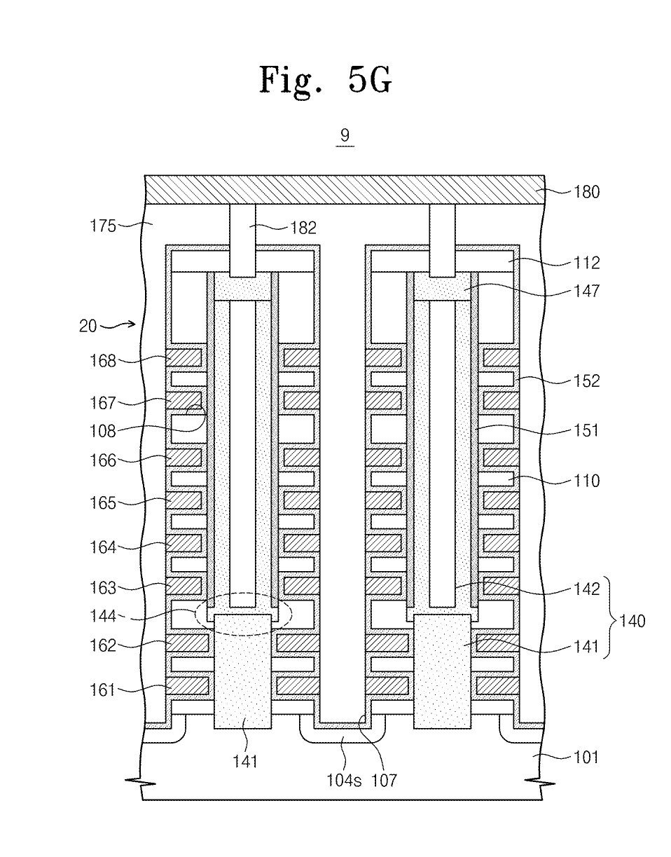

FIGS. 5A to 5D are cross-sectional views illustrating a method for fabricating a semiconductor memory device according to example embodiments of inventive concepts. FIGS. 5E to 5G are cross-sectional views illustrating steps of methods for fabricating a semiconductor memory device according to example embodiments of inventive concepts.

Referring to FIG. 5A, a method for fabricating a semiconductor memory device according to example embodiments of inventive concepts may include the same processes as or similar processes to the processes described with reference to FIGS. 1A to 1E. That is, the mold stack 10 including insulating layers 110 and sacrificial layers 120 alternately stacked may be formed on the substrate 101, the vertical channel hole 103 may be formed to penetrate the mold stack 10 and to expose the substrate 101, and the lower channel 141 may be formed to partially fill the vertical channel hole 103 and to be in contact with the substrate 101. The first data storage layer 151, the first semiconductor layer 143, and the opening 105 may be formed by the processes described with reference to FIGS. 2A to 2E. The first data storage layer 151 and the first semiconductor layer 143 may vertically extend along the inner sidewall of the vertical channel hole 103, and the opening 105 may expose the lower channel 141.

Referring to FIG. 5B, the first semiconductor layer 143 may be selectively removed. The first semiconductor layer 143 may be removed using a dry or wet etching process. For example, the first semiconductor layer 143 may be removed without a damage of the first data storage layer 151 by a thermal etching process using halogen elements such as fluorine (F), chlorine (Cl), and/or bromine (Br).

Referring to FIG. 5C, a second semiconductor layer 145 having a cylinder shape may be formed to vertical extend along the first data storage layer 151 and to partially or fully fill the opening 105, and a filling layer 191 may be formed to fill the vertical channel hole 103. Thus, an upper channel 142 may be formed to have a macaroni structure. The upper channel 142 may be in contact with the lower channel 141 to constitute a vertical channel 140. The body contact 144 corresponding to the bottom portion of the second semiconductor layer 145 may have a pillar or bulk shape, so that the body contact 144 may provide a sufficient space necessary for a current flow from the lower channel 141 toward the upper channel 142 or vice versa. Since the first semiconductor layer 143 is removed, it is possible to omit a process curing crystal defects in the first semiconductor layer 143.

Referring to FIG. 5D, the same processes as or similar processes to the processes described with reference to FIGS. 1H to 1K may be performed to form a semiconductor memory device 6 including a gate stack 20 and a bit line 180. Gates 161 to 168 vertically stacked and space apart from each other and a second data storage layer 152 may be formed to realize the gate stack 20. The bit line 180 may be formed on the interlayer insulating layer 173, so that the bit line 180 may be electrically connected to the vertical channel 140 through the plug penetrating the interlayer insulating layer 173. The semiconductor memory device 6 may include the body contact 144 having the pillar or bulk shape. Thus, a cutting phenomenon of the lower channel 141 and the upper channel 142 may be suppressed to realize a good current flow between the lower channel 141 and the upper channel 142.

Alternatively, the same processes as or similar processes to the processes described with reference to FIGS. 3A to 3F may be applied to form a semiconductor memory device 7 of FIG. 5E having the vertical channel 140 which has an uneven shape capable of inducing an electric field focus according to example embodiments of inventive concepts. Alternatively, the same processes as or similar processes to the processes described with reference to FIGS. 3H to 3I may be applied to form a semiconductor memory device 8 of FIG. 5F including the gate insulating layer 153 surrounding the sidewall of the lower channel 141 according to example embodiments of inventive concepts. Alternatively, the same processes as or similar processes to the processes described with reference to FIGS. 4A to 4G may be applied to forming a semiconductor memory device 9 of FIG. 5G including the body contact 144 capping the top portion of the lower channel 141 according to example embodiments of inventive concepts.

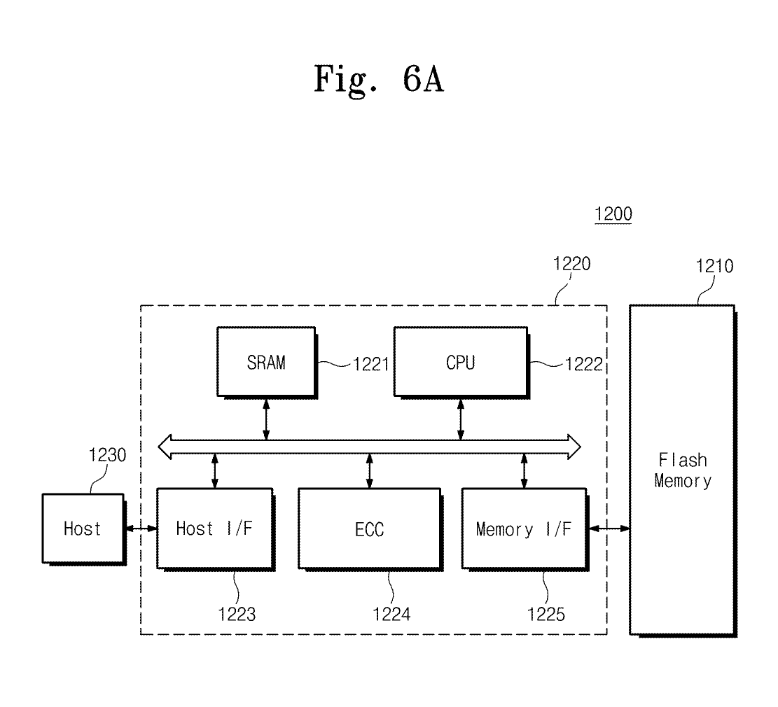

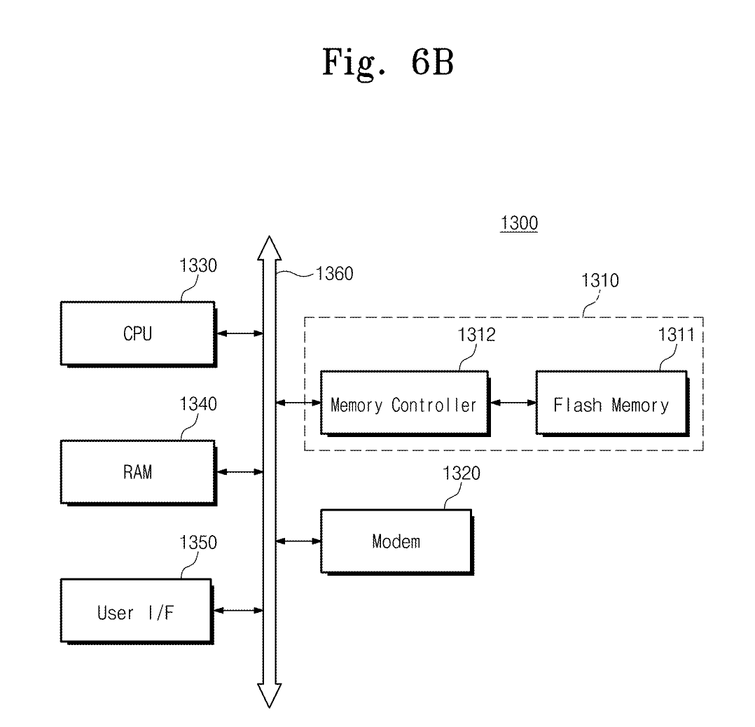

FIG. 6A is a schematic block diagram illustrating an example of memory cards including semiconductor memory devices according to example embodiments of inventive concepts. FIG. 6B is a schematic block diagram illustrating an example of information process systems including semiconductor memory devices according to example embodiments of inventive concepts.

Referring to FIG. 6A, a flash memory 1210 including at least one of the semiconductor memory devices 1 to 9 according to example embodiments of inventive concepts may be applied to a memory card 1200. The memory card 1200 may include a memory controller 1220 that controls data communication between a host 1230 and the semiconductor memory 1210. A SRAM device 1221 may be used as an operation memory of a central processing unit (CPU) 1222. A host interface unit 1223 may be configured to include a data communication protocol of the host 1230 connected to the memory card 1200. An error check and correction (ECC) block 1224 may detect and correct errors of data which are read out from the semiconductor memory 1210. A memory interface unit 1225 may be interfaced with the semiconductor memory 1210. The central processing unit (CPU) 1222 may control overall operations of the memory controller 1220.

Referring to FIG. 6B, an information processing system 1300 may include a memory system 1310 having at least one of the semiconductor memory devices 1 to 9 according to example embodiments of inventive concepts. The information processing system 1300 may include a mobile system, a computer or the like. In an embodiment, the information processing system 1300 may include the memory system 1310, a modulator-demodulator (MODEM) 1320, a central processing unit (CPU) 1330, a random access memory (RAM) device 1340 and a user interface unit 1350 that communicate with each other through a data bus 1360. The memory system 1310 may include a memory 1311 and a memory controller 1312. The memory system 1310 may have substantially the same configuration as the memory card 1200 of FIG. 6A. The memory system 1310 may store data processed by the CPU 1330 or data transmitted from an external system. The information processing system 1300 may be applied to a memory card, a solid state disk (SSD), a camera image sensor or an application chipset. The memory system 1310 may consist of the SSD. In this case, the information processing system 1300 may stably and reliably store a massive data into the memory system.

According to example embodiments of inventive concepts, the upper channel of the macaroni structure may be connected to the lower channel of the bulk structure, thereby constituting the vertical channel. Thus, a cutting margin between the lower channel and the upper channel may be increased. As a result, the good and stable connection between the lower channel and the upper channel may be realized to provide a stable current path. Thus, it is possible to realize the vertical flash memory device with improved electrical characteristics.

While some example embodiments of inventive concepts have been particularly shown and described, it will be apparent to those skilled in the art that various changes and modifications may be made without departing from the spirit and scope of the claims. Therefore, it should be understood that the above-discussed example embodiments of inventive concepts are not limiting, but illustrative. Thus, the scope of example embodiments of inventive concepts is to be determined by the broadest permissible interpretation of the following claims and their equivalents, and shall not be restricted or limited by the foregoing description.

1. A semiconductor memory device comprising:
a plurality of gates vertically stacked on a substrate;
a vertical channel penetrating the plurality of gates,
the vertical channel including a lower channel connected to the substrate and an upper channel on the lower channel,
the upper channel including a vertical pattern that penetrates some of the plurality of gates and defines an inner space, and
the upper channel including a horizontal pattern that extends horizontally along a top surface of the lower channel and contacts the top surface of the lower channel;
a data storage pattern between the vertical channel and the plurality of gates; and
an insulating layer in the inner space of the vertical pattern of the upper channel.

2. The semiconductor memory device of claim 1, wherein a material of the lower channel is the same as a material of the substrate.

3. The semiconductor memory device of claim 1, wherein a width of the horizontal pattern of the upper channel is greater than or equal to a width of the top surface of the lower channel.

4. The semiconductor memory device of claim 1, wherein the horizontal pattern surrounds an upper portion of a sidewall of the lower channel.

5. The semiconductor memory device of claim 1, wherein the vertical pattern is one of a:
a multi-layer structure including,
a first semiconductor layer in contact with the data storage pattern, and
a second semiconductor layer in contact with and surrounding the insulating layer; and
a single-layer structure surrounding the insulating layer,
the single-layer structure being in contact with the data storage pattern and the insulating layer.

6. The semiconductor memory device of claim 1, wherein the upper channel of the vertical channel extends vertically and unevenly.

7. The semiconductor memory device of claim 1, wherein
the plurality of gates include sidewalls and sidewall-corners, and
the upper channel of the vertical channel includes bent portions that are adjacent to the sidewalls and sidewall-corners of the plurality of gates.

8-20. (canceled)

21. A semiconductor device, comprising:
a stack including a plurality of gate electrodes vertically stacked on a substrate,
the stack defining at least one opening that exposes the substrate;
a lower channel in the opening of the stack and on the substrate;
a data storage pattern covering a sidewall of the opening of the stack;
an upper channel in the opening of the stack,
the upper channel including a base that extends horizontally between a top surface of the lower channel and a part of the data storage pattern, and
the upper channel including a vertical portion that extends from the base of the upper channel along the data storage layer.

22. The semiconductor device of claim 21, further comprising:
an insulating layer filling an inner space defined by the vertical portion of the upper channel.

23. The semiconductor device of claim 21, wherein
the stack includes a plurality of insulating interlayers between the plurality of gate electrodes, and
a width of the opening of the stack is wider at a level of one of the plurality of insulating interlayers than a width of the opening of the stack at a level of one of the plurality of gate electrodes.

24. The semiconductor device of claim 21, wherein a material of the lower channel is the same as a material of the substrate.

25. The semiconductor device of claim 21, wherein the base of the upper channel contacts a sidewall of the lower channel.
